(19) United States
(12) Patent Application Publication
(10) Pub. No.: US 2024/0244967 A1
(43) Pub. Date: Jul. 18, 2024

(54) Organic Light Emitting Diode and Organic Light Emitting Device Including the Same

(71) Applicants: LG Display Co., Ltd., Seoul (KR); Korea University Research and Business Foundation, Seoul (KR)

(72) Inventors: Joon-Beom Im, Paju-si (KR); Gyeong-Woo Kim, Paju-si (KR); Ji-Seon Jang, Paju-si (KR); Han-Jin Ahn, Paju-si (KR); Jun-Yun Kim, Paju-si (KR); Dong-Hoon Choi, Paju-si (KR); Min-Ju Cho, Seoul (KR); Min-Ji Kang, Seoul (KR)

(21) Appl. No.: 18/504,980

(22) Filed: Nov. 8, 2023

(30) Foreign Application Priority Data
Dec. 30, 2022 (KR) 10-2022-0190480

(51) Int. Cl. H10K 85/60; C09K 11/06; H10K 85/30; H10K 85/40

(52) U.S. Cl. CPC H10K 85/6572; C09K 11/06; H10K 85/346; H10K 85/40; H10K 85/615; H10K 85/657; H10K 85/6574; H10K 85/6576; H10K 50/11

(57) ABSTRACT

An organic light emitting diode includes a first electrode; a second electrode facing the first electrode; and a first emitting part including a first emitting material layer and positioned between the first and second electrodes, wherein the first emitting material layer includes a first p-type host and a first n-type host, and wherein the first p-type host is represented by Formula 1, and the first n-type host is represented by Formula 3.

### CROSS-REFERENCE TO RELATED APPLICATIONS

The present application claims the benefit of Korean Patent Application No. 10-2022-0190480 filed in the Republic of Korea on Dec. 30, 2022, which is hereby incorporated by reference in its entirety.

### BACKGROUND

### Technical Field

The present disclosure relates to an organic light emitting diode, and more particularly, to an organic light emitting diode having high emitting efficiency and improved lifespan and an organic light emitting device including the organic light emitting diode.

### Discussion of the Related Art

Recently, requirement for flat panel display devices having small occupied area is increased. Among the flat panel display devices, a technology of an organic light emitting display device, which includes an organic light emitting diode (OLED), is rapidly developed.

The OLED includes a cathode as an electron injection electrode, an anode as a hole injection electrode and an emitting material layer therebetween. When electrons from the cathode and holes from the anode enter into the emitting material layer, the electrons and holes are combined to generate an exciton, and the exciton is transformed from an excited state to a ground state. As a result, the light is emitted from the OLED. The OLED can be formed on a flexible transparent substrate, e.g., a plastic substrate, and can be driven by low voltage. In addition, the OLED has low power consumption and high color sense.

The organic light emitting display device includes an organic light emitting diode (OLED), and the OLED includes a first electrode, a second electrode and an organic light emitting layer therebetween.

For example, the organic light emitting display device includes red, green, and blue pixel regions, and the OLED is formed in each pixel region.

However, the OLED does not have sufficient emitting efficiency and lifespan so that the organic light emitting display device has a limitation in the emitting efficiency and the lifespan.

### SUMMARY

Accordingly, embodiments of the present disclosure are directed to an OLED and an organic light emitting device that substantially obviate one or more of the problems associated with the limitations and disadvantages of the related art.

An object of the present disclosure is to provide an OLED and an organic light emitting device having high emitting efficiency and improved lifespan.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is an organic light emitting diode comprising a first electrode; a second electrode facing the first electrode; and a first emitting part including a first emitting material layer and positioned between the first electrode and the second electrode, wherein the first emitting material layer includes a first p-type host and a first n-type host, wherein the first p-type host is represented by Formula 1:

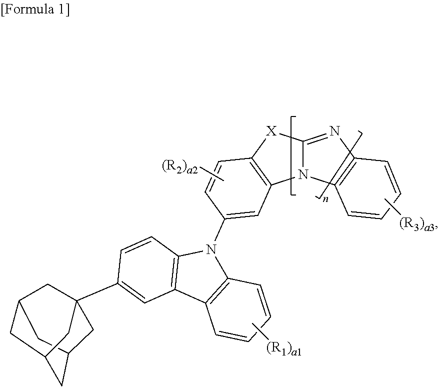

wherein in the Formula 1, each of a1 and a3 is independently an integer of 0 to 4, a2 is an integer of 0 to 3, n is 0 or 1, X is NR₄, O or S, each of R₁, R₂ and R₃ is independently selected from the group consisting of hydrogen, deuterium, halogen, cyano, a substituted or unsubstituted C1 to C10 alkyl group, a substituted or unsubstituted C1 to C10 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and R₄ is selected from the group consisting of hydrogen, deuterium, halogen, cyano, a substituted or unsubstituted C1 to C10 alkyl group, a substituted or unsubstituted C1 to C10 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, wherein the first n-type host is represented by Formula 3:

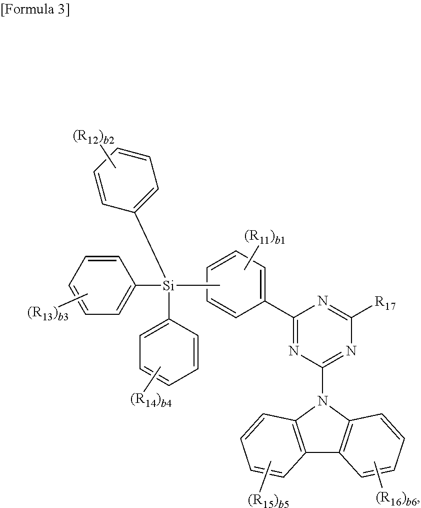

wherein in the Formula 3, each of b1, b5, and b6 is independently an integer of 0 to 4, each of b2 to b4 is independently an integer of 0 to 5, and each of R₁₁ to R₁₇ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

Another aspect of the present disclosure is an organic light emitting device comprising a substrate; the above organic light emitting diode of the present disclosure and disposed over the substrate; and an encapsulation layer covering the organic light emitting diode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is a schematic cross-sectional view of an OLED according to a third embodiment of the present disclosure.

FIG. 5 is a schematic circuit diagram of an organic light emitting display device according to a fourth embodiment of the present disclosure.

FIG. 6 is a schematic circuit diagram of an organic light emitting display device according to a fifth embodiment of the present disclosure.

FIG. 7 is a schematic cross-sectional view of an OLED according to a sixth embodiment of the present disclosure.

FIG. 8 is a schematic cross-sectional view of an OLED according to a seventh embodiment of the present disclosure.

FIGS. 9A to 9E are graphs showing an emission wavelength of an exciplex generated by a p-type host and an n-type host in an OLED of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

In the present disclosure, an organic light emitting device may be an organic light emitting display device or an organic lightening device. As an example, an organic light emitting display device, which is a display device including the OLED of the present disclosure, will be mainly described.

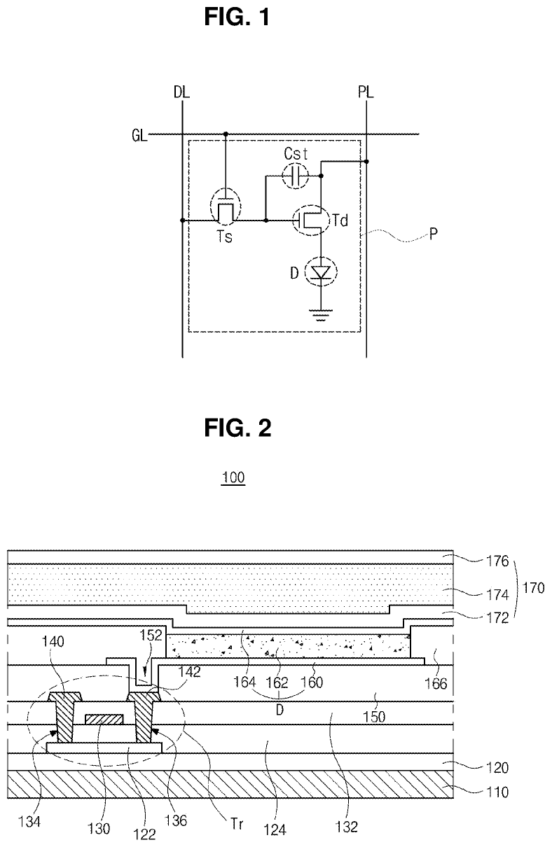

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region may include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr.

The substrate 110 may be a glass substrate or a flexible substrate. For example, the substrate 110 may be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 120 is formed on the substrate, and the TFT Tr is formed on the buffer layer 120. The buffer layer 120 may be omitted.

A semiconductor layer 122 is formed on the buffer layer 120. The semiconductor layer 122 may include an oxide semiconductor material or polycrystalline silicon.

When the semiconductor layer 122 includes the oxide semiconductor material, a light-shielding pattern (not shown) may be formed under the semiconductor layer 122. The light to the semiconductor layer 122 is shielded or blocked by the light-shielding pattern such that thermal degradation of the semiconductor layer 122 can be prevented. On the other hand, when the semiconductor layer 122 includes polycrystalline silicon, impurities may be doped into both sides of the semiconductor layer 122.

A gate insulating layer 124 of an insulating material is formed on the semiconductor layer 122. The gate insulating layer 124 may be formed of an inorganic insulating material such as silicon oxide or silicon nitride.

A gate electrode 130, which is formed of a conductive material, e.g., metal, is formed on the gate insulating layer 124 to correspond to a center of the semiconductor layer 122. In FIG. 2, the gate insulating layer 124 is formed on an entire surface of the substrate 110. Alternatively, the gate insulating layer 124 may be patterned to have the same shape as the gate electrode 130.

An interlayer insulating layer 132 of an insulating material is formed on the gate electrode 130 and over an entire surface of the substrate 110. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 122. The first and second contact holes 134 and 136 are positioned at both sides of the gate electrode 130 to be spaced apart from the gate electrode 130.

The first and second contact holes 134 and 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 140 and a drain electrode 142, which are formed of a conductive material, e.g., metal, are formed on the interlayer insulating layer 132.

The source electrode 140 and the drain electrode 142 are spaced apart from each other with respect to the gate electrode 130 and respectively contact both sides of the semiconductor layer 122 through the first and second contact holes 134 and 136.

The semiconductor layer 122, the gate electrode 130, the source electrode 140 and the drain electrode 142 constitute the TFT Tr. The TFT Tr serves as a driving element. Namely, the TFT Tr is the driving TFT Td (of FIG. 1).

In the TFT Tr, the gate electrode 130, the source electrode 140, and the drain electrode 142 are positioned over the semiconductor layer 122. Namely, the TFT Tr has a coplanar structure.

Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 150 is formed on an entire surface of the substrate 110 to cover the source and drain electrodes 140 and 142. The planarization layer 150 provides a flat top surface and has a drain contact hole 152 exposing the drain electrode 142 of the TFT Tr.

The OLED D is disposed on the planarization layer 150 and includes a first electrode 160, which is connected to the drain electrode 142 of the TFT Tr, an organic light emitting layer 162 and a second electrode 164. The organic light emitting layer 162 and the second electrode 164 are sequentially stacked on the first electrode 160. The OLED D is positioned in each of the red, green and blue pixel regions and respectively emits the red, green and blue light.

One of the first and second electrodes 160 and 164 is an anode, and the other one of the first and second electrodes 160 and 164 is a cathode. For example, the first electrode 160 may be the anode, and the second electrode 164 may be the cathode.

The first electrode 160 is separately formed in each pixel region. The first electrode 160 may be an anode and may be formed of a conductive material, e.g., a transparent conductive oxide (TCO), having a relatively high work function. For example, the first electrode 160 may be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

In a bottom-emission type organic light emitting display device 100, the first electrode 160 may have a single-layered structure of the transparent conductive oxide material layer. Namely, the first electrode 160 may be a transparent electrode.

Alternatively, in a top-emission type organic light emitting display device 100, the first electrode 160 may further include a reflective layer to have a double-layered structure or a triple-layered structure. Namely, the first electrode 160 may be a reflective electrode. For example, the reflective layer may be formed of one of silver (Ag) or aluminum-palladium-copper alloy (APC). For example, the first electrode 160 may have a double-layered structure of Ag/ITO or APC/ITO or a triple-layered structure of ITO/Ag/ITO or ITO/APC/ITO.

In addition, a bank layer 166 is formed on the planarization layer 150 to cover an edge of the first electrode 160. Namely, the bank layer 166 is positioned at a boundary of the pixel region and exposes a center of the first electrode 160 in the pixel region.

The organic light emitting layer 162 is formed on the first electrode 160. The organic light emitting layer 162 may have a single-layered structure of an emitting material layer (EML). Alternatively, the organic light emitting layer 162 may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

In the OLED D of the present disclosure, the EML includes a p-type host represented by Formula 1 and an n-type host represented by Formula 3. For example, in the blue pixel region, the organic light emitting layer 162 includes a blue EML, and the blue EML may include the p-type host represented by Formula 1 and the n-type host represented by Formula 3. In addition, the blue EML may further include a dopant (e.g., an emitter) represented by Formula 5. As a result, the OLED D and the organic light emitting display device 100 according to the present disclosure can have high emitting efficiency and improved lifespan.

Two or more EMLs of the organic light emitting layer 162 may be disposed to be separated from each other so that the OLED D may have a tandem structure.

The second electrode 164 is formed over the substrate 110 where the organic light emitting layer 162 is formed. The second electrode 164 covers an entire surface of the display area and may be formed of a conductive material having a relatively low work function to serve as a cathode. For example, the second electrode 164 may be formed of high reflective material, e.g., aluminum (Al), magnesium (Mg), calcium (Ca), silver (Ag), their alloy or their combination.

In the top-emission type organic light emitting display device 100, the second electrode 164 may have a thin profile to be transparent (or semi-transparent). For example, in the top-emission type organic light emitting display device 100, the second electrode 164 may be formed of Mg:Ag and may have a thickness of 5 to 30 nm. In this case, a weight % ratio of Mg to Ag may be 1:9 to 9:1, e.g., 1:9 to 3:7. Alternatively, in the bottom-emission type organic light emitting display device 100, the second electrode 164 may be formed of Al.

An encapsulation layer (or an encapsulation film) 170 is formed on the second electrode 164 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

In the bottom-emission type organic light emitting display device 100, a metal encapsulation plate may be disposed over the encapsulation layer 170.

The organic light emitting display device 100 may include a color filter layer corresponding to the red, green and blue pixel regions. The color filter layer may include red, green and blue color filters respectively corresponding to the red, green and blue pixel regions. When the organic light emitting display device 100 includes the color filter layer, the color purity can be improved.

In the bottom-emission type organic light emitting display device 100, the color filter layer may be disposed between the OLED D and the substrate 110, e.g., between the interlayer insulating layer 132 and the planarization layer 150. In the top-emission type organic light emitting display device 100, the color filter layer may be disposed over the OLED D, e.g., over the second electrode 164 or over the encapsulation layer 170.

The organic light emitting display device 100 may further include a polarization plate for reducing an ambient light reflection. For example, the polarization plate may be a circular polarization plate. In the bottom-emission type organic light emitting display device 100, the polarization plate may be disposed under the substrate 110. In the top-emission type organic light emitting display device 100, the polarization plate may be disposed on or over the encapsulation layer 170.

In addition, the organic light emitting display device 100 may further include a cover window on or over the encapsulation layer 170 or the polarization plate. In this instance, the substrate 110 and the cover window have a flexible property such that a flexible organic light emitting display device may be provided.

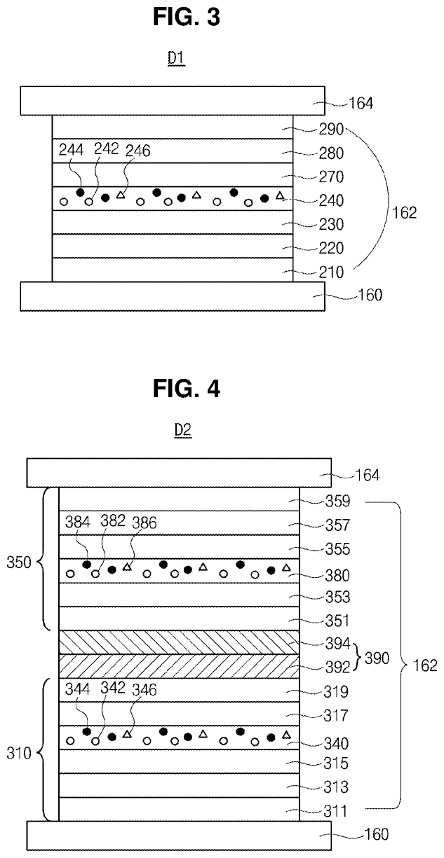

FIG. 3 is a schematic cross-sectional view of an OLED according to a second embodiment of the present disclosure.

As shown in FIG. 3, the OLED D1 includes first and second electrodes 160 and 164, which face each other, and an organic light emitting layer 162 therebetween. The organic light emitting layer 162 includes an emitting material layer (EML) 240.

The organic light emitting display device 100 (of FIG. 2) may include a red pixel region, a green pixel region, and a blue pixel region. The organic light emitting display device 100 may further include a white pixel region. The OLED D1 may be positioned in the blue pixel region, and the EML 240 is a blue EML.

The organic light emitting layer 162 in the red pixel region includes a red EML, and the organic light emitting layer 162 in the green pixel region includes a green EML.

One of the first and second electrodes 160 and 164 is an anode, and the other one of the first and second electrodes 160 and 164 is a cathode. For example, the first electrode 160 is the anode, and the second electrode 164 is the cathode. One of the first and second electrodes 160 and 164 may be a reflective electrode, and the other one of the first and second electrodes 160 and 164 may be a transparent (or a semi-transparent) electrode.

In the top-emission type OLED D1, the first electrode 160 may have a structure of ITO/Ag/ITO or a structure of ITO/APC/ITO, and the second electrode 164 may be formed of Mg:Ag.

In the bottom-emission type OLED D1, the first electrode 160 may include a transparent conductive material layer formed of ITO or IZO, and the second electrode 164 may be formed of Al.

The EML, e.g., the blue EML 240, includes a p-type host 242 and an n-type host 244. An exciplex is generated by the p-type and n-type hosts 242 and 244. For example, the p-type host 242 may have a maximum emission wavelength in a range of 350 to 390 nm, the n-type host 244 may have a maximum emission wavelength in a range of 410 to 450 nm, and the exciplex generated by the p-type and n-type hosts 242 and 244 may have a maximum emission wavelength in a range of 435 to 470 nm.

The p-type host 242 includes one or more first host compound represented by Formula 1.

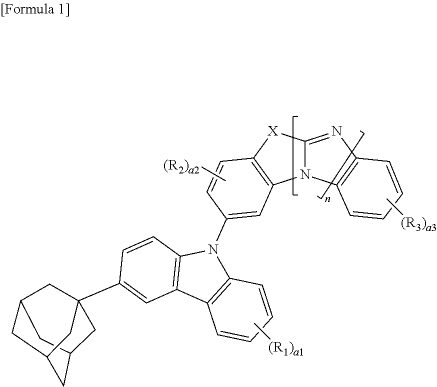

In Formula 1, each of a1 and a3 is independently an integer of 0 to 4, a2 is an integer of 0 to 3, n is 0 or 1,

X is NR₄, O or S,

each of R₁, R₂ and R₃ is independently selected from the group consisting of hydrogen, deuterium, halogen, cyano, a substituted or unsubstituted C1 to C10 alkyl group, a substituted or unsubstituted C1 to C10 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and

R₄ is selected from the group consisting of hydrogen, deuterium, halogen, cyano, a substituted or unsubstituted C1 to C10 alkyl group, a substituted or unsubstituted C1 to C10 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In the present disclosure, without specific definition, a substituent of an alkyl group, an alkoxy group, a cycloalkyl group, an aryl group, a heteroaryl group, an arylamino group and an arylsilyl group may be independently selected from the group consisting of a substituted or unsubstituted C1 to C10 alkyl group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In the present disclosure, without specific definition, a C1 to C10 alkyl group may be selected from the group consisting of methyl, ethyl, propyl and butyl, e.g., tert-butyl.

In the present disclosure, without specific definition, a C1 to C10 alkoxy group may be selected from the group consisting of methoxy, ethoxy, propoxy and butoxy, e.g., tert-butoxy.

In the present disclosure, without specific definition, a C3 to C30 cycloalkyl group may be selected from the group consisting of cyclopropyl, cyclobutyl, cyclopentyl, cyclohexyl and adamantanyl.

In the present disclosure, without specific definition, a C6 to C30 arylamino group may be selected from the group consisting of diphenylamino.

In the present disclosure, without specific definition, a C6 to C30 arylsilyl group may be selected from the group consisting of triphenylsilyl.

In the present disclosure, without specific definition, a C6 to C30 aryl group may be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C30 heteroaryl group may be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, isoquinolinyl, cinnolinyl, quinazolinyl, quinozolinyl, quinolinyl, purinyl, phthalazinyl, quinoxalinyl, benzoquinolinyl, benzoisoquinolinyl, benzoquinazolinyl, benzoquinoxalinyl, acridinyl, phenanthrolinyl, perimidinyl, phenanthridinyl, pteridinyl, cinnolinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In Formula 1, each of a1, a2 and a3 may be 0.

Formula 1 may be represented by Formula 1-1 or Formula 1-2.

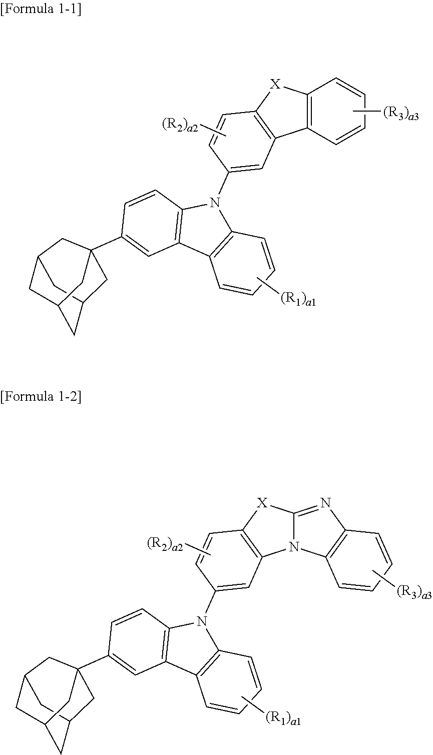

In each of Formulas 1-1 and 1-2, the definitions of a1, a2, a3, R1, R2, R3 and X are same as those in Formula 1.

For example, the p-type host 242 may include at least one of compounds in Formula 2.

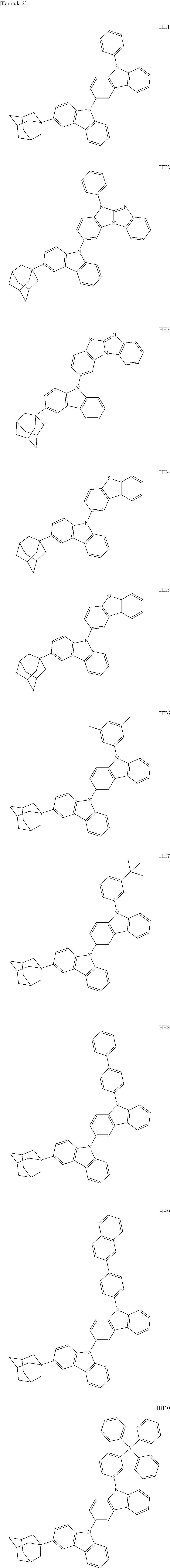

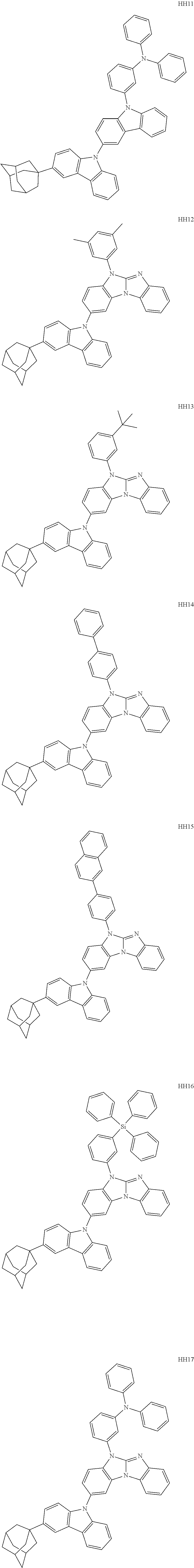

The n-type host 244 includes one or more second host compound represented by Formula 3.

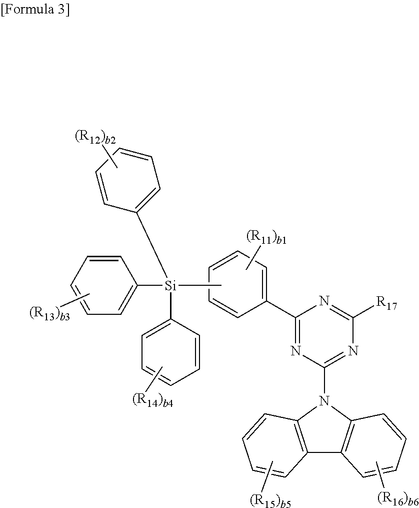

In Formula 3, each of b1, b5, and b6 is independently an integer of 0 to 4, each of b2 to b4 is independently an integer of 0 to 5, and

each of R₁₁ to R₁₇ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In Formula 3, b5 may be 1, and R₁₅ may be a substituted or unsubstituted C3 to C30 heteroaryl group, e.g., carbazolyl.

In Formula 3, R₁₇ may be selected from the group consisting of a substituted or unsubstituted C6 to C30 aryl group, e.g., phenyl or triphenylsilylphenyl, and a substituted or unsubstituted C3 to C30 heteroaryl group, e.g., carbazolyl.

For example, the n-type host 244 may include at least one of compounds in Formula 4.

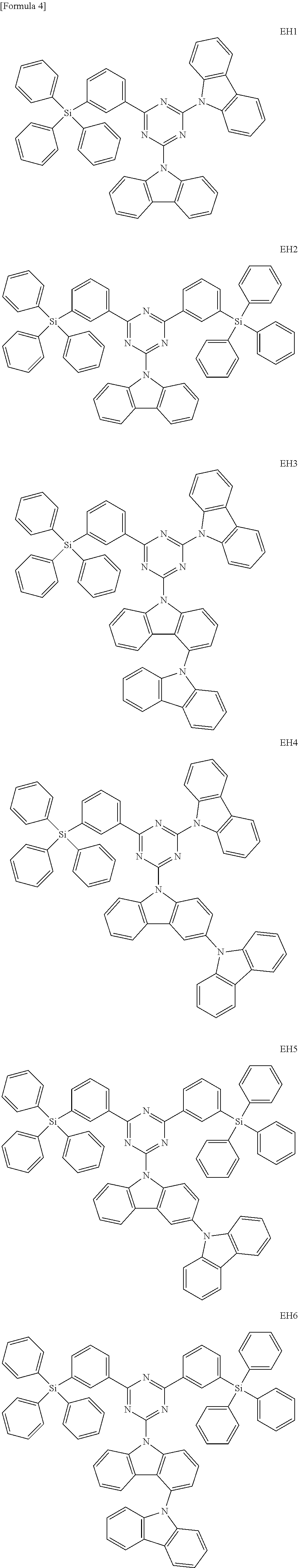

The blue EML 240 may further include a dopant (e.g., an emitter) 246. For example, the dopant 246 may be represented by Formula 5.

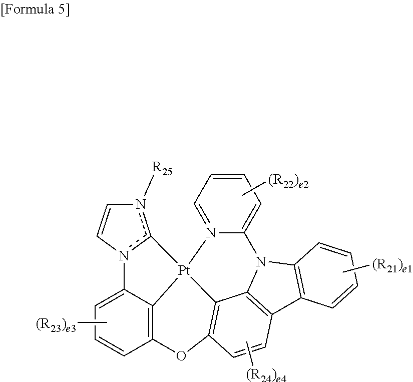

In Formula 5, each of e1 and e2 is independently an integer of 0 to 4, e3 is an integer of 0 to 3, and e4 is an integer of 0 to 2,

each of R₂₁ to R₂₄ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and

R₂₅ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In Formula 5, each of R₂₁ to R₂₅ may be independently a substituted or unsubstituted C1 to C20 alkyl group, e.g., methyl or tert-butyl, and at least one of e1 to e4 may be a positive integer.

For example, the dopant 246 may be at least one of compounds in Formula 6.

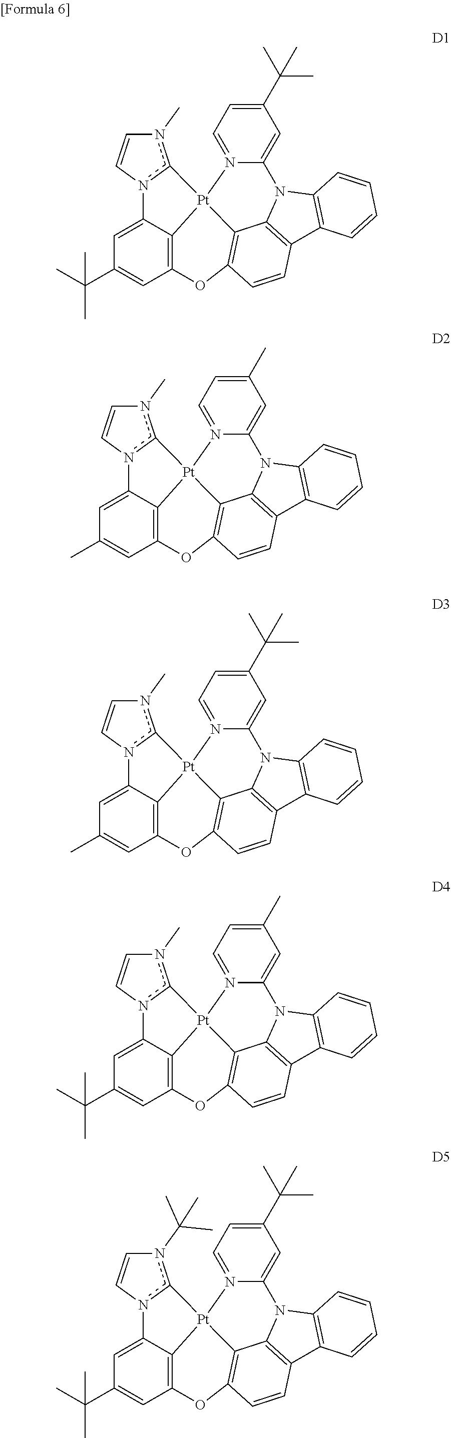

A highest occupied molecular orbital (HOMO) energy level of the p-type host 242 is higher than that of the n-type host 244. For example, the HOMO energy level of the p-type host 242 may be in a range of −5.7 to −5.4 eV, and the HOMO energy level of the n-type host 244 may be in a range of −5.9 to −5.8 eV.

A lowest unoccupied molecular orbital (LUMO) energy level of the p-type host 242 is higher than that of the n-type host 244. For example, the LUMO energy level of the p-type host 242 may be in a range of −2.2 to −2.0 eV, and the LUMO energy level of the n-type host 244 may be in a range of −2.9 to −2.7 eV.

A triplet energy of each of the p-type host 242 and the n-type host 244 may be in a range of 2.9 to 3.1 eV.

The blue EML 240 may have a thickness of 10 to 100 nm, e.g., 20 to 50 nm.

In the blue EML 240, a weight % of each of the p-type host 242 and the n-type host 244 may be greater than that of the dopant 246. A weight % of the p-type host 242 and a weight % of the n-type host 244 may be same or different.

For example, in the blue EML 240, with respect to the dopant 246, each of the p-type host 242 and the n-type host 244 may have a part by weight of 200 to 400.

As described above, an exciplex is generated by the p-type host 242 and the n-type host 244. Namely, the p-type host 242 has a first maximum emission wavelength, the n-type host 244 has a second maximum emission wavelength, and the exciplex generated by the p-type host 242 and the n-type host 244 has a third maximum emission wavelength being longer than each of the first and second maximum emission wavelengths.

When the EML 240 is a red EML, the red EML 240 may include the p-type host represented by Formula 1, the n-type host represented by Formula 3 and a red dopant. For example, the red dopant may be one of a red phosphorescent compound, a red fluorescent compound and a red delayed fluorescent compound.

When the EML 240 is a green EML, the green EML 240 may include the p-type host represented by Formula 1, the n-type host represented by Formula 3 and a green dopant. For example, the green dopant may be one of a green phosphorescent compound, a green fluorescent compound and a green delayed fluorescent compound.

The light emitting layer 162 further includes at least one of a hole transporting layer (HTL) 220 under the EML 240 and an electron transporting layer (ETL) 280 over the EML 240. The HTL 220 is positioned between the first electrode 160 and the EML 240, and the ETL 270 is positioned between the second electrode 164 and the EML 240.

In addition, the light emitting layer 162 may further include at least one of a hole injection layer (HIL) 210 between the first electrode 160 and the HTL 220 and an electron injection layer (EIL) 290 between the second electrode 164 and the ETL 280.

Moreover, the light emitting layer 162 may further include at least one of an electron blocking layer (EBL) 230 between the HTL 220 and the EML 240 and a hole blocking layer (HBL) 270 between the EML 240 and the ETL 280.

For example, the light emitting layer 162 may have a structure of the HIL 210, the HTL 220, the EBL 230, the EML 240, the HBL 270, the ETL 280 and the EIL 290 sequentially stacked. Alternatively, the EBL 230 and the HBL 270 may be omitted so that the light emitting layer 162 may have a structure of the HIL 210, the HTL 220, the EML 240, the ETL 280 and the EIL 290 sequentially stacked.

For example, the HIL 210 may include a hole injection material being one of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile(dipyrazino[2,3-f:2′ 3′-h]quinoxaline-2,3,6,7,10,11-hexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, and N,N′-diphenyl-N,N′-di[4-(N,N-diphenyl-amino)phenyl]benzidine (NPNPB), but it is not limited thereto. For example, the hole injection material of the HIL 210 may be a compound in Formula 7. The HIL 210 may have a thickness of 1 to 20 nm, e.g., 5 to 15 nm.

The HTL 220 may include a hole transporting material being one of N,N′-diphenyl-N,N′-bis(3-methylphenyl)-1,1′-biphenyl-4,4′-diamine (TPD), NPB (or NPD), 4,4′-bis(N-carbazolyl)-1,1′-biphenyl (CBP), poly[N,N′-bis(4-butylpnehyl)-N,N′-bis(phenyl)-benzidine] (poly-TPD), (poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, and N-([1,1′-biphenyl]-4-yl)-9,9-dimethyl-N-(4-(9-phenyl-9H-carbazol-3-yl)phenyl)-9H-fluoren-2-amine, but it is not limited thereto. For example, the hole transporting material of the HTL 220 may be a compound in Formula 8. The HTL 220 may have a thickness of 30 to 150 nm, e.g., 30 to 120 nm.

The ETL 280 may include an electron transporting material being one of tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl)4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline (TPQ), diphenyl-4-triphenylsilyl-phenylphosphine oxide (TSPO1), and 2-[4-(9,10-di-2-naphthalen2-yl-2-anthracen-2-yl)phenyl]-1-phenyl-1H-benzimidazole (ZADN), but it is not limited thereto. For example, the electron transporting material of the ETL 280 may be a compound in Formula 11. The ETL 280 may have a thickness of 10 to 50 nm, e.g., 20 to 40 nm.

The EIL 290 may include an electron injection material being one of LiF, CsF, NaF, BaF₂, Liq, lithium benzoate, and sodium stearate, but it is not limited thereto. For example, the EIL 290 may have a thickness of 0.5 to 5 nm.

The EBL 230, which is positioned between the HTL 220 and the EML 240 to block the electron transfer from the EML 240 into the HTL 220, may include an electron blocking material being one of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene, but it is not limited thereto. For example, the electron blocking material of the EBL 230 may be a compound in Formula 9. The EBL 230 may have a thickness of 1 to 20 nm, e.g., 5 to 15 nm.

The HBL 270, which is positioned between the EML 240 and the ETL 280 to block the hole transfer from the EML 240 into the ETL 280, may include the material of the ETL 280. For example, the material of the HBL 270 may include a hole blocking material being one of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1, but it is not limited thereto. For example, the hole blocking material of the HBL 270 may be a compound in Formula 10. The HBL 270 may have a thickness of 1 to 20 nm, e.g., 5 to 15 nm.

The top-emission type OLED D1 may further include a capping layer for enhancing a light extraction efficiency. For example, the capping layer may be formed on the second electrode 164 and may include the above-mentioned hole transporting material.

In the OLED D1 of the present disclosure, the EML 240, e.g., the blue EML 240, includes the p-type host 242 represented by Formula 1 and the n-type host 244 represented by Formula 3. In addition, the blue EML 240 may further include the dopant 246 represented by Formula 5. An exciplex is generated by the p-type host 242 and the n-type host 244 in the blue EML 240, and an electrical stress onto the dopant 246 can be reduced by the exciplex.

Accordingly, in the OLED D1 and the organic light emitting display device 100 of the present disclosure, at least one of the emitting efficiency and the lifespan can be improved.

FIG. 4 is a schematic cross-sectional view of an OLED according to a third embodiment of the present disclosure.

As illustrated in FIG. 4, the OLED D2 includes first and second electrodes 160 and 164 facing each other and an organic light emitting layer 162 therebetween. The organic light emitting layer 162 includes a first emitting part 310 including a blue EML 340 and a second emitting part 350 including a second EML 380. The organic light emitting layer 162 may include a CGL 390 between the first and second emitting parts 310 and 350.

The organic light emitting display device 100 may include a red pixel region, a green pixel region and a blue pixel region. In addition, the organic light emitting display device 100 may further include a white pixel region. The OLED D2 may be positioned in the blue pixel region, and each of the first and second EMLs 340 and 380 may be a blue EML.

One of the first and second electrodes 160 and 164 is an anode, and the other one of the first and second electrodes 160 and 164 is a cathode. For example, the first electrode 160 is the anode, and the second electrode 164 is the cathode. One of the first and second electrodes 160 and 164 may be a reflective electrode, and the other one of the first and second electrodes 160 and 164 may be a transparent (or a semi-transparent) electrode.

In the top-emission type OLED D2, the first electrode 160 may have a structure of ITO/Ag/ITO or a structure of ITO/APC/ITO, and the second electrode 164 may be formed of Mg:Ag.

In the bottom-emission type OLED D2, the first electrode 160 may include a transparent conductive material layer formed of ITO or IZO, and the second electrode 164 may be formed of Al.

The CGL 390 is positioned between the first and second emitting parts 310 and 350 so that the first emitting part 310, the CGL 390, the second emitting part 350 may be sequentially stacked on the first electrode 160. Namely, the first emitting part 310 is positioned between the first electrode 160 and the CGL 390, and the second emitting part 350 is positioned between the second electrode 164 and the CGL 390.

The first EML 340, e.g., the first blue EML 340, includes a first p-type host 342 and a first n-type host 344. An exciplex is generated by the first p-type and first n-type hosts 342 and 344. For example, the first p-type host 342 may have a maximum emission wavelength in a range of 350 to 390 nm, the first n-type host 344 may have a maximum emission wavelength in a range of 410 to 450 nm, and the exciplex generated by the first p-type and first n-type hosts 342 and 344 may have a maximum emission wavelength in a range of 435 to 470 nm.

The first p-type host 342 includes one or more first host compound represented by Formula 1, and the first n-type host 344 includes one or more second host compound represented by Formula 3.

For example, the first p-type host 342 may include one or more of the compounds in Formula 2, and the first n-type host 344 may include one or more of the compounds in Formula 4.

The first blue EML 340 may further include a first dopant 346 represented by Formula 5. For example, the first dopant 346 may be at least one of the compounds in Formula 6.

A highest occupied molecular orbital (HOMO) energy level of the first p-type host 342 is higher than that of the first n-type host 344. For example, the HOMO energy level of the first p-type host 342 may be in a range of −5.7 to −5.4 eV, and the HOMO energy level of the first n-type host 344 may be in a range of −5.9 to −5.8 eV.

A lowest unoccupied molecular orbital (LUMO) energy level of the first p-type host 342 is higher than that of the first n-type host 344. For example, the LUMO energy level of the first p-type host 342 may be in a range of −2.2 to −2.0 eV, and the LUMO energy level of the first n-type host 344 may be in a range of −2.9 to −2.7 eV.

A triplet energy of each of the first p-type host 342 and the first n-type host 344 may be in a range of 2.9 to 3.1 eV.

The first blue EML 340 may have a thickness of 10 to 100 nm, e.g., 20 to 50 nm.

In the first blue EML 340, a weight % of each of the first p-type host 342 and the first n-type host 344 may be greater than that of the first dopant 346. A weight % of the first p-type host 342 and a weight % of the first n-type host 344 may be same or different.

For example, in the first blue EML 340, with respect to the first dopant 346, each of the first p-type host 342 and the first n-type host 344 may have a part by weight of 200 to 400.

The first emitting part 310 may further include at least one of a first HTL 313 under the first blue EML 340 and a first ETL 319 over the first blue EML 340. Namely, the first HTL 313 is positioned between the first blue EML 340 and the first electrode 160, and the first ETL 319 is positioned between the first blue EML 340 and the second emitting part 350.

In addition, the first emitting part 310 may further include an HIL 311 between the first electrode 160 and the first HTL 313.

Moreover, the first emitting part 310 may further include at least one of a first EBL 315 between the first HTL 313 and the first blue EML 340 and a first HBL 317 between the first blue EML 340 and the first ETL 319.

For example, the first emitting part 310 may have a structure of the HIL 311, the first HTL 313, the first EBL 315, the first blue EML 340, the first HBL 317 and the first ETL 319 sequentially stacked on the first electrode 160. Alternatively, the first EBL 315 and the first HBL 317 may be omitted so that the first emitting part 310 may have a structure of the HIL 311, the first HTL 313, the first blue EML 340 and the first ETL 319 sequentially stacked on the first electrode 160.

The second EML 380, e.g., the second blue EML 380, includes a second p-type host 382 and a second n-type host 384. An exciplex is generated by the second p-type host 382 and the second n-type host 384. For example, the second p-type host 382 may have a maximum emission wavelength in a range of 350 to 390 nm, the second n-type host 384 may have a maximum emission wavelength in a range of 410 to 450 nm, and the exciplex generated by the second p-type host 382 and the second n-type host 384 may have a maximum emission wavelength in a range of 435 to 470 nm.

The second p-type host 382 includes one or more first host compound represented by Formula 1, and the second n-type host 384 includes one or more second host compound represented by Formula 3.

For example, the second p-type host 382 may include one or more of the compounds in Formula 2, and the second n-type host 384 may include one or more of the compounds in Formula 4. The first p-type host 342 and the second p-type host 382 may be same or different, and the first n-type host 344 and the second n-type host 384 may be same or different.

The second blue EML 380 may further include a second dopant 386 represented by Formula 5. For example, the second dopant 386 may be at least one of the compounds in Formula 6. The first dopant 346 and the second dopant 386 may be same or different.

A highest occupied molecular orbital (HOMO) energy level of the second p-type host 382 is higher than that of the second n-type host 384. For example, the HOMO energy level of the second p-type host 382 may be in a range of −5.7 to −5.4 eV, and the HOMO energy level of the second n-type host 384 may be in a range of −5.9 to −5.8 eV.

A lowest unoccupied molecular orbital (LUMO) energy level of the second p-type host 382 is higher than that of the second n-type host 384. For example, the LUMO energy level of the second p-type host 382 may be in a range of −2.2 to −2.0 eV, and the LUMO energy level of the second n-type host 384 may be in a range of −2.9 to −2.7 eV.

A triplet energy of each of the second p-type host 382 and the second n-type host 384 may be in a range of 2.9 to 3.1 eV.

The second blue EML 380 may have a thickness of 10 to 100 nm, e.g., 20 to 50 nm. The thickness of the first blue EML 340 and the thickness of the second blue EML 380 may be same or different.

In the second blue EML 380, a weight % of each of the second p-type host 382 and the second n-type host 384 may be greater than that of the second dopant 386. A weight % of the second p-type host 382 and a weight % of the second n-type host 384 may be same or different.

For example, in the second blue EML 380, with respect to the second dopant 386, each of the second p-type host 382 and the second n-type host 384 may have a part by weight of 200 to 400. The weight % of the first p-type host 342 in the first blue EML 340 and the weight % of the second p-type host 382 in the second blue EML 380 may be same or different. The weight % of the first n-type host 344 in the first blue EML 340 and the weight % of the second n-type host 384 in the second blue EML 380 may be same or different. The weight % of the first dopant 346 in the first blue EML 340 and the weight % of the second dopant 386 in the second blue EML 380 may be same or different.

The second emitting part 350 may further include at least one of a second HTL 351 under the second blue EML 380 and a second ETL 357 over the second blue EML 380. Namely, the second HTL 351 is positioned between the second blue EML 380 and the first emitting part 310, and the second ETL 357 is positioned between the second blue EML 380 and the second electrode 164.

In addition, the second emitting part 350 may further include an EIL 359 between the second electrode 164 and the second ETL 357.

Moreover, the second emitting part 350 may further include at least one of a second EBL 353 between the second HTL 351 and the second EML 380 and a second HBL 355 between the second EML 380 and the second ETL 357.

For example, the second emitting part 350 may have a structure of the second HTL 351, the second EBL 353, the second blue EML 380, the second HBL 355, the second ETL 357 and the EIL 359 sequentially stacked on the first electrode 160. Alternatively, the second EBL 353 and the second HBL 355 may be omitted so that the second emitting part 350 may have a structure of the second HTL 351, the second blue EML 380, the second ETL 357 and the EIL 359 sequentially stacked on the first electrode 160.

The HIL 332 may include the above-mentioned hole injection material and may have a thickness of 1 to 20 nm, e.g., 5 to 15 nm.

Each of the first and second HTLs 313 and 351 may include the above-mentioned hole transporting material and may have a thickness of 30 to 150 nm, e.g., 30 to 120 nm.

Each of the first and second ETLs 319 and 357 may include the above-mentioned electron transporting material and may have a thickness of 10 to 50 nm, e.g., 20 to 40 nm.

The EIL 359 may include the above-mentioned electron injection material and may have a thickness of 0.1 to 10 nm, e.g., 0.5 to 5 nm.

Each of the first and second EBLs 315 and 353 may include the above-mentioned electron blocking material and may have a thickness of 1 to 20 nm, e.g., 5 to 15 nm.

Each of the first and second HBLs 317 and 355 may include the above-mentioned hole blocking material and may have a thickness of 1 to 20 nm, e.g., 5 to 15 nm.

The CGL 390 is positioned between the first and second emitting parts 310 and 350. Namely, the first and second emitting parts 310 and 350 is connected to each other through the CGL 390. The CGL 390 may be a PN-junction CGL of an N-type CGL 392 and a P-type CGL 394.

The N-type CGL 392 is positioned between the first ETL 319 and the second HTL 351, and the P-type CGL 394 is positioned between the N-type CGL 392 and the second HTL 351.

The N-type CGL 392 may be an organic layer doped with an alkali metal, e.g., Li, Na, K and Cs, and/or an alkali earth metal, e.g., Mg, Sr, Ba and Ra. For example, the N-type CGL 392 may be formed of an N-type charge generation material including a host being the organic material, e.g., 4,7-dipheny-1,10-phenanthroline (Bphen) and MTDATA, a dopant being an alkali metal and/or an alkali earth metal, and the dopant may be doped with a weight % of 0.01 to 30.

The P-type CGL 394 may be formed of a P-type charge generation material including an inorganic material, e.g., tungsten oxide (WOx), molybdenum oxide (MoOx), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The top-emission type OLED D2 may further include a capping layer for enhancing a light extraction efficiency. For example, the capping layer may be formed on the second electrode 164 and may include the above-mentioned hole transporting material.

In FIG. 4, the first blue EML 340 includes the first p-type host 342 represented by Formula 1 and the first n-type host 344 represented by Formula 3, and the second blue EML 380 includes the second p-type host 382 represented by Formula 1 and the second n-type host 384 represented by Formula 3.

Alternatively, one of the first and second blue EMLs 340 and 380 includes the p-type host represented by Formula 1 and the n-type host represented by Formula 3, and the other one of the first and second blue EMLs 340 and 380 may include a blue host being different from the p-type host represented by Formula 1 and the n-type host represented by Formula 3.

In FIG. 4, the first blue EML 340 includes the first dopant 346 represented by Formula 5, and the second blue EML 380 includes the second dopant 386 represented by Formula 5.

Alternatively, one of the first and second blue EMLs 340 and 380 includes the dopant represented by Formula 5, and the other one of the first and second blue EMLs 340 and 380 may include a blue dopant being different from the dopant represented by Formula 5.

For example, the blue host may be selected from the group consisting of mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPO1), and 9,9′-(5-(triphenylsilyl)-1,3-phenylene)bis(9H-carbazole) (SimCP).

For example, the blue dopant may be selected from the group consisting of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spirofluorene (spiro-DPVBi), [1,4-bis[2-[4-[N,N-di(p-tolyl)amino]phenyl]vinyl] benzene (DSB), 1-4-di-[4-(N,N-diphenyl)amino]styryl-benzene (DSA), 2,5,8,11-tetra-tetr-butylperylene (TBPe), bis((2-hydroxylphenyl)-pyridine)beryllium (Bepp2), 9-(9-Phenylcarbazole-3-yl)-10-(naphthalene-1-yl)anthracene (PCAN), mer-tris(1-phenyl-3-methylimidazolin-2-ylidene-C,C(2)′iridium(III) (mer-Ir(pmi)3), fac-Tris(1,3-diphenyl-benzimidazolin-2-ylidene-C,C(2)′iridium(III) (fac-Ir(dpbic)3), bis(3,4,5-trifluoro-2-(2-pyridyl)phenyl-(2-carboxypyridyl)iridium(III) (Ir(tfpd)2pic), tris(2-(4,6-difluorophenyl)pyridine))iridium(III) (Ir(Fppy)3), and bis[2-(4,6-difluorophenyl)pyridinato-C2,N](picolinato)iridium(III) (FIrpic).

The OLED D2 of the present disclosure includes the first emitting part 310 including the first EML 340 and the second emitting part 350 including the second EML 380, and at least one of the first and second EMLs 340 and 380, e.g., the first and second blue EMLs 340 and 380, includes the p-type host represented by Formula 1, the n-type host represented by Formula 3 and the dopant represented by Formula 5.

Accordingly, in the OLED D2 and the organic light emitting display device 100 of the present disclosure, at least one of the emitting efficiency and the lifespan can be improved.

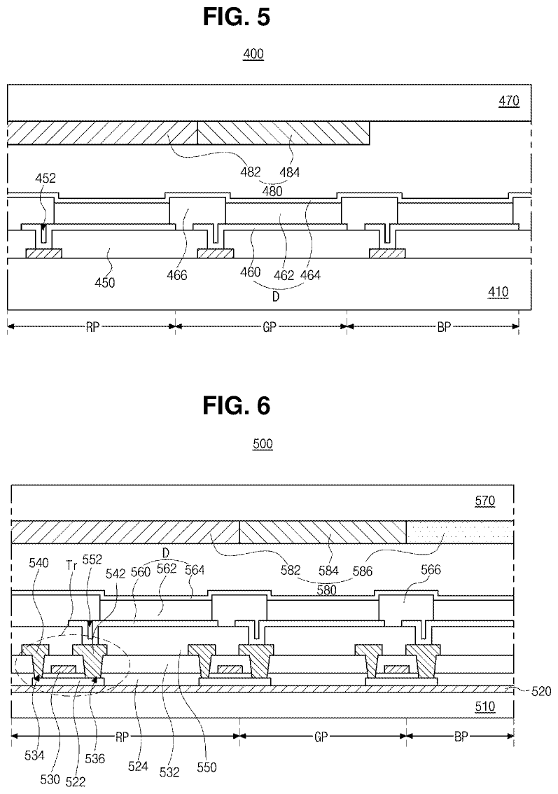

FIG. 5 is a schematic circuit diagram of an organic light emitting display device according to a fourth embodiment of the present disclosure.

As illustrated in FIG. 5, the organic light emitting display device 400 includes a first substrate 410, where a red pixel region RP, a green pixel region GP, and a blue pixel region BP are defined, a second substrate 470 facing the first substrate 410, an OLED D, which is positioned between the first and second substrates 410 and 470 and providing white emission, and a color conversion layer 480 between the OLED D and the second substrate 470.

Although not shown, a color filter may be formed between the second substrate 470 and each color conversion layer 480.

Each of the first and second substrates 410 and 470 may be a glass substrate or a flexible substrate. For example, each of the first and second substrates 410 and 470 may be a polyimide (PI) substrate, a polyethersulfone (PES) substrate, a polyethylenenaphthalate (PEN) substrate, a polyethylene terephthalate (PET) substrate or a polycarbonate (PC) substrate.

A TFT Tr, which corresponding to each of the red, green, and blue pixels RP, GP and BP, is formed on the first substrate 410, and a planarization layer 450, which has a drain contact hole 452 exposing an electrode, e.g., a drain electrode, of the TFT Tr is formed to cover the TFT Tr.

The OLED D including a first electrode 460, an organic light emitting layer 462 and a second electrode 464 is formed on the planarization layer 450. In this instance, the first electrode 460 may be connected to the drain electrode of the TFT Tr through the drain contact hole 452.

A bank layer 466 is formed on the planarization layer 450 to cover an edge of the first electrode 460. Namely, the bank layer 466 is positioned at a boundary of the pixel region and exposes a center of the first electrode 460 in the pixel region.

The OLED D emits a blue light and may have a structure shown in one of FIGS. 3 and 4. Namely, the OLED D is formed in each of the red, green, and blue pixels RP, GP, and BP and provides the blue light.

For example, referring to FIG. 3, the organic light emitting layer 462 of the OLED D includes the blue EML 240, and the blue EML 240 includes the p-type host 242 represented by Formula 1 and the n-type host 244 represented by Formula 3. The blue EML 240 may further include the dopant 246 represented by Formula 5.

Referring to FIG. 4, the organic light emitting layer 462 of the OLED D includes the first blue EML 340 and the second blue EML 380. The first blue EML 340 includes the first p-type host 342 represented by Formula 1 and the first n-type host 344 represented by Formula 3, and the second blue EML 380 includes the second p-type host 382 represented by Formula 1 and the second n-type host 384 represented by Formula 3. In addition, the first blue EML 340 may further include the first dopant 346 represented by Formula 5, and the second blue EML 380 may further include the second dopant 386 represented by Formula 5.

The color conversion layer 480 includes a first color conversion layer 482 corresponding to the red pixel region RP and a second color conversion layer 484 corresponding to the green pixel region GP. For example, the color conversion layer 480 may include an inorganic color conversion material such as a quantum dot.

The blue light from the OLED D is converted into the red light by the first color conversion layer 482 in the red pixel region RP, and the blue light from the OLED D is converted into the green light by the second color conversion layer 484 in the green pixel region GP.

Accordingly, the organic light emitting display device 400 can display a full-color image.

Although not shown, a color filter layer may be disposed between the second substrate 470 and the color conversion layer 480. The color filter layer may include a red color filter corresponding to the red pixel region RP and a green color filter corresponding to the green pixel region GP.

When the light from the OLED D passes through the first substrate 410 to display an image, the color conversion layer 480 may be disposed between the OLED D and the first substrate 410. In this configuration, the color filter layer may be disposed between the first substrate 410 ad the color conversion layer 480.

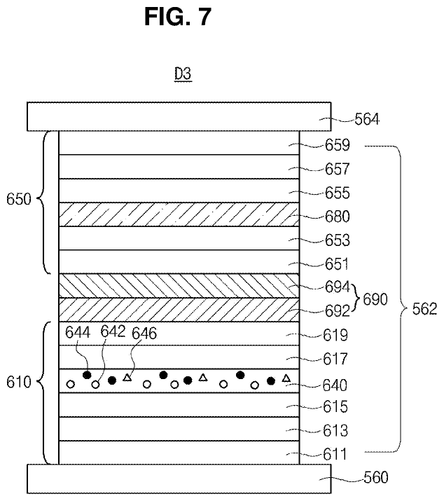

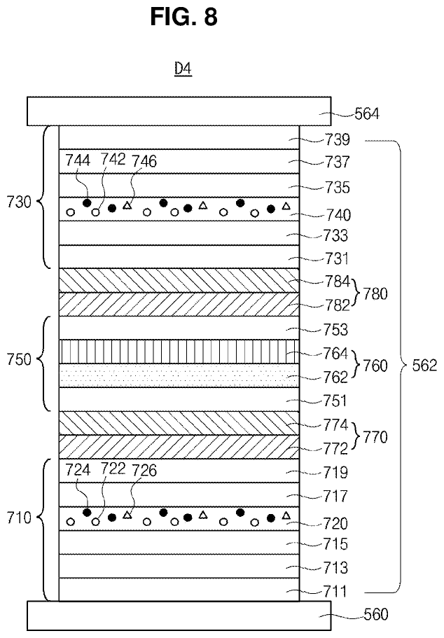

FIG. 6 is a schematic circuit diagram of an organic light emitting display device according to a fifth embodiment of the present disclosure. FIG. 7 is a schematic cross-sectional view of an OLED according to a sixth embodiment of the present disclosure, and FIG. 8 is a schematic cross-sectional view of an OLED according to a seventh embodiment of the present disclosure.

As shown in FIG. 6, the organic light emitting display device 500 includes a first substrate 510, where a red pixel region RP, a green pixel region GP and a blue pixel region BP are defined, a second substrate 570 facing the first substrate 510, an OLED D, which is positioned between the first and second substrates 510 and 570 and providing white emission, and a color filter layer 580 between the OLED D and the second substrate 570.

Each of the first and second substrates 510 and 570 may be a glass substrate or a flexible substrate. For example, each of the first and second substrates 510 and 570 may be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 520 is formed on the substrate, and the TFT Tr corresponding to each of the red, green and blue pixel regions RP, GP, and BP is formed on the buffer layer 520. The buffer layer 520 may be omitted.

A semiconductor layer 522 is formed on the buffer layer 520. The semiconductor layer 522 may include an oxide semiconductor material or polycrystalline silicon.

A gate insulating layer 524 is formed on the semiconductor layer 522. The gate insulating layer 524 may be formed of an inorganic insulating material such as silicon oxide or silicon nitride.

A gate electrode 530, which is formed of a conductive material, e.g., metal, is formed on the gate insulating layer 524 to correspond to a center of the semiconductor layer 522.

An interlayer insulating layer 532, which is formed of an insulating material, is formed on the gate electrode 530. The interlayer insulating layer 532 may be formed of an inorganic insulating material, e.g., silicon oxide or silicon nitride, or an organic insulating material, e.g., benzocyclobutene or photo-acryl.

The interlayer insulating layer 532 includes first and second contact holes 534 and 536 exposing both sides of the semiconductor layer 522. The first and second contact holes 534 and 536 are positioned at both sides of the gate electrode 530 to be spaced apart from the gate electrode 530.

A source electrode 540 and a drain electrode 542, which are formed of a conductive material, e.g., metal, are formed on the interlayer insulating layer 532.

The source electrode 540 and the drain electrode 542 are spaced apart from each other with respect to the gate electrode 530 and respectively contact both sides of the semiconductor layer 522 through the first and second contact holes 534 and 536.

The semiconductor layer 522, the gate electrode 530, the source electrode 540, and the drain electrode 542 constitute the TFT Tr. The TFT Tr serves as a driving element. Namely, the TFT Tr may correspond to the driving TFT Td (of FIG. 1).

Although not shown, the gate line and the data line cross each other to define the pixel region, and the switching TFT is formed to be connected to the gate and data lines. The switching TFT is connected to the TFT Tr as the driving element.

In addition, the power line, which may be formed to be parallel to and spaced apart from one of the gate and data lines, and the storage capacitor for maintaining the voltage of the gate electrode of the TFT Tr in one frame may be further formed.

A planarization layer 550, which includes a drain contact hole 552 exposing the drain electrode 542 of the TFT Tr, is formed to cover the TFT Tr.

A first electrode 560, which is connected to the drain electrode 542 of the TFT Tr through the drain contact hole 552, is separately formed in each pixel region and on the planarization layer 550. The first electrode 560 may be an anode and may be formed of a conductive material having a relatively high work function. For example, the first electrode 560 may be formed of a transparent conductive material, e.g., indium-tin-oxide (ITO) or indium-zinc-oxide (IZO).

A reflective electrode or a reflective layer may be disposed under the first electrode 560. For example, the reflective electrode or the reflective layer may be formed of silver (Ag) or aluminum-palladium-copper (APC) alloy. In this instance, the first electrode 560 may have a double-layered structure of Ag/ITO or APC/ITO or a triple-layered structure of ITO/Ag/ITO or ITO/APC/ITO.

A bank layer 566 is formed on the planarization layer 550 to cover an edge of the first electrode 560. Namely, the bank layer 566 is positioned at a boundary of the pixel region and exposes a center of the first electrode 560 in the pixel region. The bank layer 566 may be omitted.

An organic emitting layer 562 is formed on the first electrode 560.

Referring to FIG. 7, the OLED D3 includes the first and second electrodes 560 and 564 facing each other and the organic emitting layer 562 between the first and second electrodes 560 and 564. The organic light emitting layer 562 includes a first emitting part 610 including a first EML 640 and a second emitting part 650 including a second EML 680. The organic light emitting layer 562 may include a CGL 690 between the first and second emitting parts 610 and 650.

The organic light emitting display device 500 may include a red pixel region, a green pixel region and a blue pixel region, and the OLED D3 corresponds to the red, green, and blue pixel regions.

The CGL 690 is positioned between the first and second emitting parts 610 and 650 so that the first emitting part 610, the CGL 690, the second emitting part 650 may be sequentially stacked on the first electrode 560. Namely, the first emitting part 610 is positioned between the first electrode 560 and the CGL 690, and the second emitting part 650 is positioned between the second electrode 564 and the CGL 690.

The first EML 640 of the first emitting part 610 is a blue EML. The blue EML 640 includes a first p-type host 642 and a first n-type host 644. An exciplex is generated by the first p-type and first n-type hosts 642 and 644. For example, the first p-type host 642 may have a maximum emission wavelength in a range of 350 to 390 nm, the first n-type host 644 may have a maximum emission wavelength in a range of 410 to 450 nm, and the exciplex generated by the first p-type and first n-type hosts 642 and 644 may have a maximum emission wavelength in a range of 435 to 470 nm.

The first p-type host 642 includes one or more first host compound represented by Formula 1, and the first n-type host 644 includes one or more second host compound represented by Formula 3.

For example, the first p-type host 642 may include one or more of the compounds in Formula 2, and the first n-type host 644 may include one or more of the compounds in Formula 4.

The blue EML 640 may further include a first dopant 646 represented by Formula 5. For example, the first dopant 646 may be at least one of the compounds in Formula 6.

A highest occupied molecular orbital (HOMO) energy level of the first p-type host 642 is higher than that of the first n-type host 644. For example, the HOMO energy level of the first p-type host 642 may be in a range of −5.7 to −5.4 eV, and the HOMO energy level of the first n-type host 644 may be in a range of −5.9 to −5.8 eV.

A lowest unoccupied molecular orbital (LUMO) energy level of the first p-type host 642 is higher than that of the first n-type host 644. For example, the LUMO energy level of the first p-type host 642 may be in a range of −2.2 to −2.0 eV, and the LUMO energy level of the first n-type host 644 may be in a range of −2.9 to −2.7 eV.

A triplet energy of each of the first p-type host 642 and the first n-type host 644 may be in a range of 2.9 to 3.1 eV.

The blue EML 640 may have a thickness of 10 to 100 nm, e.g., 20 to 50 nm.

In the blue EML 640, a weight % of each of the first p-type host 642 and the first n-type host 644 may be greater than that of the first dopant 646. A weight % of the first p-type host 642 and a weight % of the first n-type host 644 may be same or different.

For example, in the blue EML 640, with respect to the first dopant 646, each of the first p-type host 642 and the first n-type host 644 may have a part by weight of 200 to 400.

The first emitting part 610 may further include at least one of a first HTL 613 under the blue EML 640 and a first ETL 619 over the blue EML 640. Namely, the first HTL 613 is positioned between the blue EML 640 and the first electrode 560, and the first ETL 619 is positioned between the blue EML 640 and the second emitting part 650.

In addition, the first emitting part 610 may further include an HIL 611 between the first electrode 560 and the first HTL 613.

Moreover, the first emitting part 610 may further include at least one of a first EBL 615 between the first HTL 613 and the blue EML 640 and a first HBL 617 between the blue EML 640 and the first ETL 619.

For example, the first emitting part 610 may have a structure of the HIL 611, the first HTL 613, the first EBL 615, the blue EML 640, the first HBL 617, and the first ETL 619 sequentially stacked on the first electrode 560. Alternatively, the first EBL 615 and the first HBL 617 may be omitted so that the first emitting part 610 may have a structure of the HIL 611, the first HTL 613, the blue EML 640 and the first ETL 619 sequentially stacked on the first electrode 560.

The second EML 680 of the second emitting part 650 is a yellow-green EML. For example, the second EML 680 may include a yellow-green host and a yellow-green dopant. The yellow-green dopant may be one of a fluorescent compound, a phosphorescent compound, and a delayed fluorescent compound.

In the second EML 680, the yellow-green host may have a weight % of about 70 to 99.9, and the yellow-green dopant may have a weight % of about 0.1 to 30.

For example, the yellow-green host may include a p-type host represented by Formula 1 and an n-type host represented by Formula 3.

Alternatively, the yellow-green host may be selected from the group consisting of mCP-CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

For example, the yellow-green dopant may be selected from the group consisting of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)irdium(III) (Ir(BT)2(acac)), bis(2-(9,9-diethytl-fluoren-2-yl)-1-phenyl-1H-benzo[d]imdiazolato)(acetylacetonate)iridium(III) (Ir(fbi)2(acac)), bis(2-phenylpyridine)(3-(pyridine-2-yl)-2H-chromen-2-onate)iridium(III) (fac-Ir(ppy)2Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III); PO-01), but it is not limited thereto.

The second emitting part 650 may further include at least one of a second HTL 651 under the second blue EML 680 and a second ETL 657 over the second blue EML 680. Namely, the second HTL 651 is positioned between the second blue EML 680 and the first emitting part 610, and the second ETL 657 is positioned between the second blue EML 680 and the second electrode 564.

In addition, the second emitting part 650 may further include an EIL 659 between the second electrode 564 and the second ETL 657.

Moreover, the second emitting part 650 may further include at least one of a second EBL 653 between the second HTL 651 and the second EML 680 and a second HBL 655 between the second EML 680 and the second ETL 657.

For example, the second emitting part 650 may have a structure of the second HTL 651, the second EBL 653, the second blue EML 680, the second HBL 655, the second ETL 657 and the EIL 659 sequentially stacked on the first electrode 560. Alternatively, the second EBL 653 and the second HBL 655 may be omitted so that the second emitting part 650 may have a structure of the second HTL 651, the second blue EML 680, the second ETL 657 and the EIL 659 sequentially stacked on the first electrode 560.

The HIL 611 may include the above-mentioned hole injection material and may have a thickness of 1 to 20 nm, e.g., 5 to 15 nm.

Each of the first and second HTLs 613 and 651 may include the above-mentioned hole transporting material and may have a thickness of 30 to 150 nm, e.g., 30 to 120 nm.

Each of the first and second ETLs 619 and 657 may include the above-mentioned electron transporting material and may have a thickness of 10 to 50 nm, e.g., 20 to 40 nm.

The EIL 659 may include the above-mentioned electron injection material and may have a thickness of 0.1 to 10 nm, e.g., 0.5 to 5 nm.

Each of the first and second EBLs 615 and 653 may include the above-mentioned electron blocking material and may have a thickness of 1 to 20 nm, e.g., 5 to 15 nm.

Each of the first and second HBLs 617 and 655 may include the above-mentioned hole blocking material and may have a thickness of 1 to 20 nm, e.g., 5 to 15 nm.

The CGL 690 is positioned between the first and second emitting parts 610 and 650. Namely, the first and second emitting parts 610 and 650 is connected to each other through the CGL 690. The CGL 690 may be a PN-junction CGL of an N-type CGL 692 and a P-type CGL 694.

The N-type CGL 692 is positioned between the first ETL 619 and the second HTL 651, and the P-type CGL 694 is positioned between the N-type CGL 692 and the second HTL 651.

The N-type CGL 692 may include the above-mentioned N-type charge generation material, and the P-type CGL 694 may include the above-mentioned P-type charge generation material.

The top-emission type OLED D3 may further include a capping layer for enhancing a light extraction efficiency. For example, the capping layer may be formed on the second electrode 564 and may include the above-mentioned hole transporting material.

In FIG. 7, the first EML 640 between the first electrode 560 and the CGL 690 is a blue EML including the p-type host 642 represented by Formula 1, the n-type host 644 represented by Formula 3 and the dopant 646 represented by Formula 5, and the second EML 680 between the second electrode 564 and the CGL 690 is a yellow-green EML.

Alternatively, the first EML 640 between the first electrode 560 and the CGL 690 may be a yellow-green EML, and the second EML 680 between the second electrode 564 and the CGL 690 may be a blue EML including the p-type host 642 represented by Formula 1, the n-type host 644 represented by Formula 3 and the dopant 646 represented by Formula 5.

In the OLED D3, the first EML 640 includes the p-type host 642 represented by Formula 1, the n-type host 644 represented by Formula 3 and the dopant 646 represented by Formula 5.

As a result, in the OLED D3 and the organic light emitting display device 500, at least one of the emitting efficiency and the lifespan can be improved.

In addition, the OLED D3 including the first emitting part 610 emitting a blue light and the second emitting part 650 emitting a yellow-green light can provide a white emission.

Referring to FIG. 8, the OLED D4 includes the first and second electrodes 560 and 564 facing each other and the organic emitting layer 562 between the first and second electrodes 560 and 564. The organic light emitting layer 562 includes a first emitting part 710 including a first EML 720, a second emitting part 730 including a second EML 740 and a third emitting part 750 including a third EML 760. The organic light emitting layer 562 may include a first CGL 770 between the first and third emitting parts 710 and 750 and a second CGL 780 between the second and third emitting part 730 and 750.

The organic light emitting display device 500 may include a red pixel region, a green pixel region and a blue pixel region, and the OLED D4 corresponds to the red, green, and blue pixel regions.

The first CGL 770 is positioned between the first and third emitting parts 710 and 750, and the second CGL 780 is positioned between the second and third emitting parts 730 and 750. Namely, the first emitting part 710, the first CGL 770, the third emitting part 750, the second CGL 780 and the second emitting part 730 are sequentially stacked on the first electrode 560. In other words, the first emitting parts 710 is positioned between the first electrode 560 and the first CGL 770, the third emitting part 750 is positioned between the first and second CGLs 770 and 780, and the second emitting part 730 is positioned between the second CGL 780 and the second electrode 564.

The first EML 720 of the first emitting part 710 is a blue EML. The first EML 720 may be referred to as a first blue EML 720. The first blue EML 720 includes a first p-type host 722 and a first n-type host 724. An exciplex is generated by the first p-type and first n-type hosts 722 and 724. For example, the first p-type host 722 may have a maximum emission wavelength in a range of 350 to 390 nm, the first n-type host 724 may have a maximum emission wavelength in a range of 410 to 450 nm, and the exciplex generated by the first p-type and first n-type hosts 722 and 724 may have a maximum emission wavelength in a range of 435 to 470 nm.

The first p-type host 722 includes one or more first host compound represented by Formula 1, and the first n-type host 724 includes one or more second host compound represented by Formula 3.

For example, the first p-type host 722 may include one or more of the compounds in Formula 2, and the first n-type host 724 may include one or more of the compounds in Formula 4.

The first blue EML 720 may further include a first dopant 726 represented by Formula 5. For example, the first dopant 726 may be at least one of the compounds in Formula 6.

A highest occupied molecular orbital (HOMO) energy level of the first p-type host 722 is higher than that of the first n-type host 724. For example, the HOMO energy level of the first p-type host 722 may be in a range of −5.7 to −5.4 eV, and the HOMO energy level of the first n-type host 724 may be in a range of −5.9 to −5.8 eV.

A lowest unoccupied molecular orbital (LUMO) energy level of the first p-type host 722 is higher than that of the first n-type host 724. For example, the LUMO energy level of the first p-type host 722 may be in a range of −2.2 to −2.0 eV, and the LUMO energy level of the first n-type host 724 may be in a range of −2.9 to −2.7 eV.

A triplet energy of each of the first p-type host 722 and the first n-type host 724 may be in a range of 2.9 to 3.1 eV.

The first blue EML 720 may have a thickness of 10 to 100 nm, e.g., 20 to 50 nm.

In the first blue EML 720, a weight % of each of the first p-type host 722 and the first n-type host 724 may be greater than that of the first dopant 726. A weight % of the first p-type host 722 and a weight % of the first n-type host 724 may be same or different.

For example, in the first blue EML 720, with respect to the first dopant 726, each of the first p-type host 722 and the first n-type host 724 may have a part by weight of 200 to 400.

The first emitting part 710 may further include at least one of a first HTL 713 under the first blue EML 720 and a first ETL 719 over the first blue EML 720. Namely, the first HTL 713 is positioned between the first blue EML 720 and the first electrode 560, and the first ETL 719 is positioned between the first blue EML 720 and the second emitting part 750.

In addition, the first emitting part 710 may further include an HIL 711 between the first electrode 560 and the first HTL 713.

Moreover, the first emitting part 710 may further include at least one of a first EBL 715 between the first HTL 713 and the first blue EML 720 and a first HBL 717 between the first blue EML 720 and the first ETL 719.

For example, the first emitting part 710 may have a structure of the HIL 711, the first HTL 713, the first EBL 715, the first blue EML 720, the first HBL 717 and the first ETL 719 sequentially stacked on the first electrode 560. Alternatively, the first EBL 715 and the first HBL 717 may be omitted so that the first emitting part 710 may have a structure of the HIL 711, the first HTL 713, the first blue EML 720, and the first ETL 719 sequentially stacked on the first electrode 560.

The second EML 740 of the second emitting part 730 is a blue EML. The second EML 740 may be referred to as a second blue EML 740. The second blue EML 740, includes a second p-type host 742 and a second n-type host 744. An exciplex is generated by the second p-type host 742 and the second n-type host 744. For example, the second p-type host 742 may have a maximum emission wavelength in a range of 350 to 390 nm, the second n-type host 744 may have a maximum emission wavelength in a range of 410 to 450 nm, and the exciplex generated by the second p-type host 742 and the second n-type host 744 may have a maximum emission wavelength in a range of 435 to 470 nm.

The second p-type host 742 includes one or more first host compound represented by Formula 1, and the second n-type host 744 includes one or more second host compound represented by Formula 3.

For example, the second p-type host 742 may include one or more of the compounds in Formula 2, and the second n-type host 744 may include one or more of the compounds in Formula 4. The first p-type host 722 and the second p-type host 742 may be same or different, and the first n-type host 724 and the second n-type host 744 may be same or different.

The second blue EML 740 may further include a second dopant 746 represented by Formula 5. For example, the second dopant 746 may be at least one of the compounds in Formula 6. The first dopant 726 and the second dopant 746 may be same or different.

A highest occupied molecular orbital (HOMO) energy level of the second p-type host 742 is higher than that of the second n-type host 744. For example, the HOMO energy level of the second p-type host 742 may be in a range of −5.7 to −5.4 eV, and the HOMO energy level of the second n-type host 744 may be in a range of −5.9 to −5.8 eV.

A lowest unoccupied molecular orbital (LUMO) energy level of the second p-type host 742 is higher than that of the second n-type host 744. For example, the LUMO energy level of the second p-type host 742 may be in a range of −2.2 to −2.0 eV, and the LUMO energy level of the second n-type host 744 may be in a range of −2.9 to −2.7 eV.

A triplet energy of each of the second p-type host 742 and the second n-type host 744 may be in a range of 2.9 to 3.1 eV.

The second blue EML 740 may have a thickness of 10 to 100 nm, e.g., 20 to 50 nm. The thickness of the first blue EML 720 and the thickness of the second blue EML 740 may be same or different.

In the second blue EML 740, a weight % of each of the second p-type host 742 and the second n-type host 744 may be greater than that of the second dopant 746. A weight % of the second p-type host 742 and a weight % of the second n-type host 744 may be same or different.

For example, in the second blue EML 740, with respect to the second dopant 746, each of the second p-type host 742 and the second n-type host 744 may have a part by weight of 200 to 400. The weight % of the first p-type host 722 in the first blue EML 720 and the weight % of the second p-type host 742 in the second blue EML 740 may be same or different. The weight % of the first n-type host 724 in the first blue EML 720 and the weight % of the second n-type host 744 in the second blue EML 740 may be same or different. The weight % of the first dopant 726 in the first blue EML 720 and the weight % of the second dopant 746 in the second blue EML 740 may be same or different.

The second emitting part 730 may further include at least one of a second HTL 731 under the second blue EML 740 and a second ETL 737 over the second blue EML 740. Namely, the second HTL 731 is positioned between the second blue EML 740 and the first emitting part 710, and the second ETL 737 is positioned between the second blue EML 740 and the second electrode 564.

In addition, the second emitting part 730 may further include an EIL 739 between the second electrode 564 and the second ETL 737.

Moreover, the second emitting part 730 may further include at least one of a second EBL 733 between the second HTL 731 and the second EML 740 and a second HBL 735 between the second EML 740 and the second ETL 737.

For example, the second emitting part 730 may have a structure of the second HTL 731, the second EBL 733, the second blue EML 740, the second HBL 735, the second ETL 737 and the EIL 739 sequentially stacked on the first electrode 560. Alternatively, the second EBL 733 and the second HBL 735 may be omitted so that the second emitting part 730 may have a structure of the second HTL 731, the second blue EML 740, the second ETL 737 and the EIL 739 sequentially stacked on the first electrode 560.

The third EML 760 of the third emitting part 750 includes a red EML 762 and a green EML 764 to emit red and green light.

The red EML 762 includes a red host and a red dopant. In the red EML 762, the red host may have a weight % of 70 to 99, and the red dopant may have a weight % of 1 to 30. For example, the red dopant may be one of a red fluorescent compound, a red phosphorescent compound and a red delayed fluorescent compound.

The red host may include a p-type host represented by Formula 1 and an n-type host represented by Formula 3. Alternatively, the red host may be selected from the group consisting of mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbipheyl (CDBP), 2,7-bis(carbazole-9-yl)-9,9-dimethylfluorene (DMFL-CBP), 2,2′,7,7′-tetrakis(carbazole-9-yl)-9,9-spiorofluorene (Spiro-CBP), and 3,6-bis(carbazole-9-yl)-9-(2-ethyl-hexyl)-9H-carbazole (TCzl), but it is not limited thereto.

The red dopant may be selected from the group consisting of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (Ir(Mphq)3), bis(2-phenylquinoline)(2,2,6,6-tetramethylheptane-3,5-dionate)iridium(III) (Ir(dpm)PQ2), bis(phenylisoquinoline)(2,2,6,6-tetramethylheptane-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (Ir(dmpq)3), bis[2-(2-methylphenyl)-7-methyl-quinoline](acetylacetonate)iridium(III) (Ir(dmpq)2(acac)), bis[2-(3,5-dimethylphenyl)-4-methyl-quinoline](acetylacetonate)iridium(III) (Ir(mphmq)2(acac)), and tris(dibenzoylmethane)mono(1,10-phenanthroline)europium(III) (Eu(dbm)3(phen)), but it is not limited thereto.

The green EML 764 includes a green host and a green dopant. In the green EML 764, the green host may have a weight % of 70 to 99, and the green dopant may have a weight % of 1 to 30. For example, the green dopant may be one of a green fluorescent compound, a green phosphorescent compound and a green delayed fluorescent compound.

The green host may include a p-type host represented by Formula 1 and an n-type host represented by Formula 3. Alternatively, the green host may be selected from the above-mentioned yellow-green host materials.

The green dopant may be selected from the group consisting of [bis(2-phenylpyridine)](pyridyl-2-benzofuro[2,3-b]pyridine)iridium, tris[2-phenylpyridine]iridium(III) (Ir(ppy)₃), fac-tris(2-phenylpyridine)iridium(III) (fac-Ir(ppy)₃), bis(2-phenylpyridine)(acetylacetonate)iridium(III) (Ir(ppy)2(acac)), tris[2-(p-tolyl)pyridine]iridium(III) (Ir(mppy)₃), bis(2-(naphthalene-2-yl)pyridine)(acetylacetonate)iridium(III) (Ir(npy)₂acac), tris(2-phenyl-3-methyl-pyridine)iidium (Ir(3mppy)₃), and fac-tris(2-(3-p-xylyl)phenyl)pyridine iridium(III) (TEG), but it is not limited thereto.

The third EML 760 of the third emitting part 750 may further include a yellow-green EML between the red and green EMLs 762 and 764 to have a triple-layered structure. The yellow-green EML may include the above-mentioned yellow-green host and the above-mentioned yellow-green dopant. The third EML 760 of the third emitting part 750 may include a yellow-green EML instead of the red and green EMLs 762 and 764.

The third emitting part 750 may further include at least one of a third HTL 751 under the third EML 760 and a third ETL 753 over the third EML 760.

In addition, the third emitting part 750 may further include at least one of a third EBL between the third HTL 751 and the third EML 760 and a third HBL between the third EML 760 and the third ETL 753.

The HIL 711 may include the above-mentioned hole injection material and may have a thickness of 1 to 20 nm, e.g., 5 to 15 nm.

Each of the first to third HTLs 713, 731, and 751 may include the above-mentioned hole transporting material and may have a thickness of 30 to 150 nm, e.g., 30 to 120 nm.

Each of the first to third ETLs 719, 737, and 753 may include the above-mentioned electron transporting material and may have a thickness of 10 to 50 nm, e.g., 20 to 40 nm.

The EIL 739 may include the above-mentioned electron injection material and may have a thickness of 0.1 to 10 nm, e.g., 0.5 to 5 nm.

Each of the first and second EBLs 715 and 733 and the third EBL may include the above-mentioned electron blocking material and may have a thickness of 1 to 20 nm, e.g., 5 to 15 nm.

Each of the first and second HBLs 717 and 735 and the third HBL may include the above-mentioned hole blocking material and may have a thickness of 1 to 20 nm, e.g., 5 to 15 nm.

The first CGL 770 is positioned between the first and third emitting parts 710 and 750, and the second CGL 780 is positioned between the second and third emitting parts 730 and 750. Namely, the first and third emitting parts 710 and 750 may be connected to each other through the first CGL 770, and the second and third emitting parts 730 and 750 may be connected to each other through the second CGL 780. The first CGL 770 may be a P-N junction CGL of a first N-type CGL 772 and a first P-type CGL 774, and the second CGL 780 may be a P-N junction CGL of a second N-type CGL 782 and a second P-type CGL 784.

In the first CGL 770, the first N-type CGL 772 is positioned between the first ETL 719 and the third HTL 751, and the first P-type CGL 774 is positioned between the first N-type CGL 772 and the third HTL 751.

In the second CGL 780, the second N-type CGL 782 is positioned between the third ETL 753 and the second HTL 731, and the second P-type CGL 784 is positioned between the second N-type CGL 782 and the second HTL 731.

Each of the first and second N-type CGLs 772 and 782 may include the above-mentioned N-type charge generation material, and each of the first and second P-type CGLs 774 and 784 may include the above-mentioned P-type charge generation material.

The top-emission type OLED D4 may further include a capping layer for enhancing a light extraction efficiency. For example, the capping layer may be formed on the second electrode 564 and may include the above-mentioned hole transporting material.

In FIG. 8, the first blue EML 720 includes the first p-type host 722 represented by Formula 1 and the first n-type host 724 represented by Formula 3, and the second blue EML 740 includes the second p-type host 742 represented by Formula 1 and the second n-type host 744 represented by Formula 3.

Alternatively, at least one of the first and second blue EMLs 720 and 740 may include the p-type host represented by Formula 1 and the n-type host represented by Formula 3, and the other one of the first and second blue EMLs 720 and 740 may include a blue host being different from the p-type host represented by Formula 1 and the n-type host represented by Formula 3. The blue host may be the above-mentioned blue host material.

In FIG. 8, the first blue EML 720 includes the first dopant 726 represented by Formula 5, and the second blue EML 740 includes the second dopant 746 represented by Formula 5.

Alternatively, one of the first and second blue EMLs 720 and 740 includes the dopant represented by Formula 5, and the other one of the first and second blue EMLs 720 and 740 may include a blue dopant being different from the dopant represented by Formula 5. The blue dopant may be the above-mentioned blue dopant material.

The OLED D4 of the present disclosure includes the first emitting part 710 including the first EML 720 (e.g., a first blue EML), the second emitting part 730 including the second EML 740 (e.g., a second blue EML) and the third emitting part 750 including the red and green EMLs (and/or the yellow-green EML), and at least one of the first and second blue EMLs 720 and 740 includes the p-type host represented by Formula 1, the n-type host represented by Formula 3 and the dopant represented by Formula 5.

Accordingly, in the OLED D4 and the organic light emitting display device 500 of the present disclosure, at least one of the emitting efficiency and the lifespan can be improved.

The OLED D4 includes the first and second emitting parts 710 and 730, each of which provides blue emission, and the third emitting part 750, which provides red and green emission (or yellow-green emission) so that white emission can be provided from the OLED D4.

In FIG. 8, the OLED4 D has a triple-stack structure of the first, second, and third emitting parts 710, 730, and 750. Alternatively, the OLED D may further include additional emitting part and CGL.

Referring to FIG. 6 again, a second electrode 564 is formed over the substrate 510 where the organic emitting layer 562 is formed.

In the organic light emitting display device 500, since the light emitted from the organic emitting layer 562 is incident to the color filter layer 580 through the second electrode 564, the second electrode 564 has a thin profile for transmitting the light.

The first electrode 560, the organic emitting layer 562 and the second electrode 564 constitute the OLED D.

The color filter layer 580 is positioned over the OLED D and includes a red color filter 582, a green color filter 584 and a blue color filter 586 respectively corresponding to the red, green and blue pixel regions RP, GP, and BP.

Although not shown, the color filter layer 580 may be attached to the OLED D by using an adhesive layer. Alternatively, the color filter layer 580 may be formed directly on the OLED D.

An encapsulation layer may be formed to prevent penetration of moisture into the OLED D. For example, the encapsulation layer may include a first inorganic insulating layer, an organic insulating layer and a second inorganic insulating layer sequentially stacked, but it is not limited thereto.

A polarization plate for reducing an ambient light reflection may be disposed over the top-emission type OLED D. For example, the polarization plate may be a circular polarization plate.

In the OLED of FIG. 6, the light of the OLED D passes through the second electrode 564, and the color filter layer 580 is disposed over the OLED D. Alternatively, when the light of the OLED D passes through the first electrode 560, the color filter layer 580 may be disposed between the OLED D and the first substrate 510.

A color conversion layer (not shown) may be formed between the OLED D and the color filter layer 580. The color conversion layer may include a red color conversion layer, a green color conversion layer and a blue color conversion layer respectively corresponding to the red, green and blue pixel regions RP, GP, and BP. The white light from the OLED D is converted into the red light, the green light, and the blue light by the red, green and blue color conversion layer, respectively.

As described above, in the organic light emitting display device 500, the OLED D in the red, green and blue pixel regions RP, GP, and BP emits the white light, and the white light from the organic light emitting diode D passes through the red color filter 582, the green color filter 584, and the blue color filter 586. As a result, the red light, the green light and the blue light are provided from the red pixel region RP, the green pixel region GP, and the blue pixel region BP, respectively.

In FIGS. 6 to 8, the OLED D emitting the white light is used for a display device. Alternatively, the OLED D may be formed on an entire surface of a substrate without at least one of the driving element and the color filter layer to be used for a lightening device. The display device and the lightening device each including the OLED D of the present disclosure may be referred to as an organic light emitting device.

### [OLED]

An anode (ITO (5 nm)/Ag (100 nm)/ITO(5 nm)), an HIL (a compound of Formula 7, 7 nm), an HTL (a compound of Formula 8, 110 nm), an EBL (a compound of Formula 9, 10 nm), a blue EML (30 nm), an HBL (a compound of Formula 10, 10 nm), an ETL (a compound of Formula 11, 30 nm), an EIL (LiF, 0.1 nm), a cathode (Mg:Ag (1:9), 12 nm) and a capping layer (a compound of Formula 8, 75 nm) are sequentially deposited to form a blue OLED.

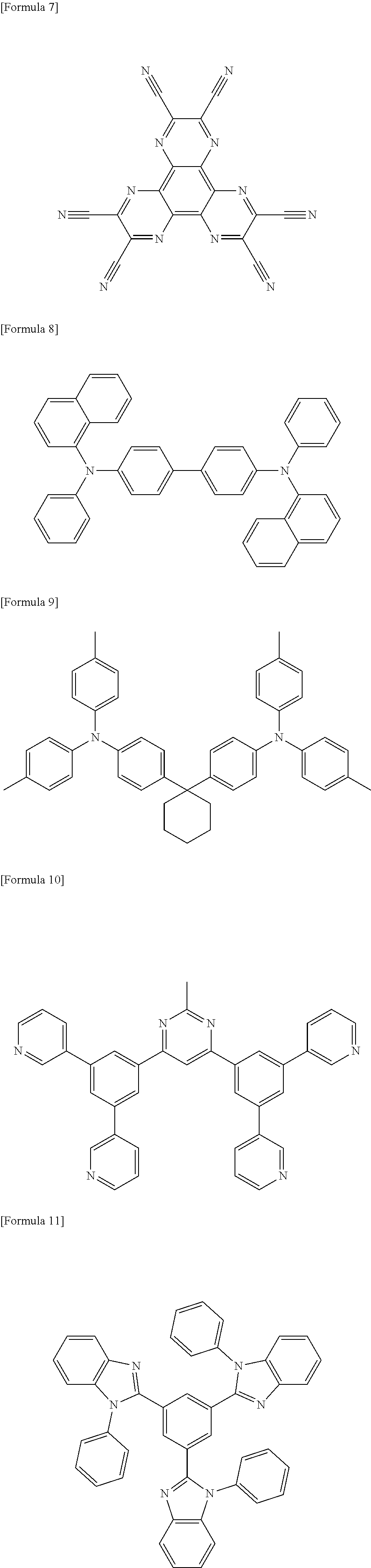

### 1. COMPARATIVE EXAMPLES

### (1) Comparative Example 1 (Ref1)

The compound A in Formula 12 (42 wt %), the compound EH1 in Formula 4 (42 wt %) and the compound D1 in Formula 6 (16 wt %) were used to form the blue EML.

### (2) Comparative Example 2 (Ref2)

The compound B in Formula 12 (42 wt %), the compound EH1 in Formula 4 (42 wt %) and the compound D1 in Formula 6 (16 wt %) were used to form the blue EML.

### (3) Comparative Example 3 (Ref3)

The compound C in Formula 12 (42 wt %), the compound EH1 in Formula 4 (42 wt %) and the compound D1 in Formula 6 (16 wt %) were used to form the blue EML.

### (4) Comparative Example 4 (Ref4)

The compound D in Formula 12 (42 wt %), the compound EH1 in Formula 4 (42 wt %) and the compound D1 in Formula 6 (16 wt %) were used to form the blue EML.

### (5) Comparative Example 5 (Ref5)

The compound E in Formula 12 (42 wt %), the compound EH1 in Formula 4 (42 wt %) and the compound D1 in Formula 6 (16 wt %) were used to form the blue EML.

### (6) Comparative Example 6 (Ref6)

The compound F in Formula 12 (42 wt %), the compound EH1 in Formula 4 (42 wt %) and the compound D1 in Formula 6 (16 wt %) were used to form the blue EML.

### (7) Comparative Example 7 (Ref7)

The compound G in Formula 12 (42 wt %), the compound EH1 in Formula 4 (42 wt %) and the compound D1 in Formula 6 (16 wt %) were used to form the blue EML.

### (8) Comparative Example 8 (Ref8)

The compound H in Formula 12 (42 wt %), the compound EH1 in Formula 4 (42 wt %) and the compound D1 in Formula 6 (16 wt %) were used to form the blue EML.

### (9) Comparative Example 9 (Ref9)

The compound I in Formula 12 (42 wt %), the compound EH1 in Formula 4 (42 wt %) and the compound D1 in Formula 6 (16 wt %) were used to form the blue EML.

### (10) Comparative Example 10 (Ref10)

The compound J in Formula 12 (42 wt %), the compound EH1 in Formula 4 (42 wt %) and the compound D1 in Formula 6 (16 wt %) were used to form the blue EML.

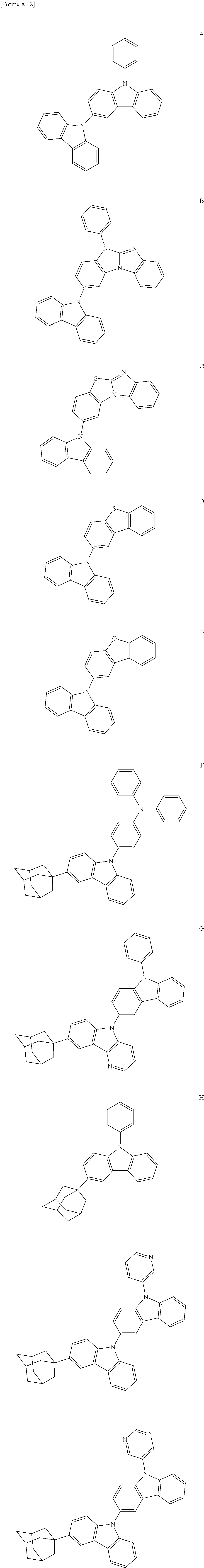

### 2. EXAMPLES

### (1) Example 1 (Ex1)

The compound HH1 in Formula 2 (42 wt %), the compound EH1 in Formula 4 (42 wt %) and the compound D1 in Formula 6 (16 wt %) were used to form the blue EML.

### (2) Example 2 (Ex2)

The compound HH2 in Formula 2 (42 wt %), the compound EH1 in Formula 4 (42 wt %) and the compound D1 in Formula 6 (16 wt %) were used to form the blue EML.

### (3) Example 3 (Ex3)

The compound HH3 in Formula 2 (42 wt %), the compound EH1 in Formula 4 (42 wt %) and the compound D1 in Formula 6 (16 wt %) were used to form the blue EML.

### (4) Example 4 (Ex4)

The compound HH4 in Formula 2 (42 wt %), the compound EH1 in Formula 4 (42 wt %) and the compound D1 in Formula 6 (16 wt %) were used to form the blue EML.

### (5) Example 5 (Ex5)

The compound HH5 in Formula 2 (42 wt %), the compound EH1 in Formula 4 (42 wt %) and the compound D1 in Formula 6 (16 wt %) were used to form the blue EML.

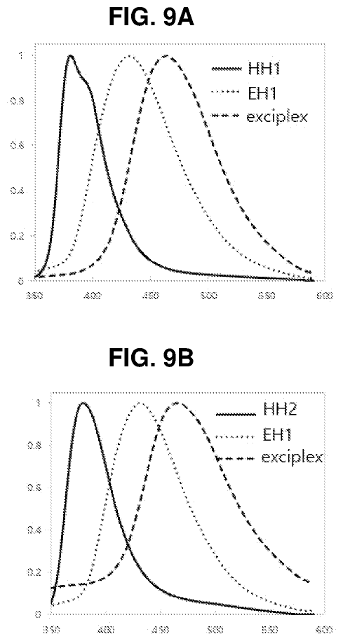

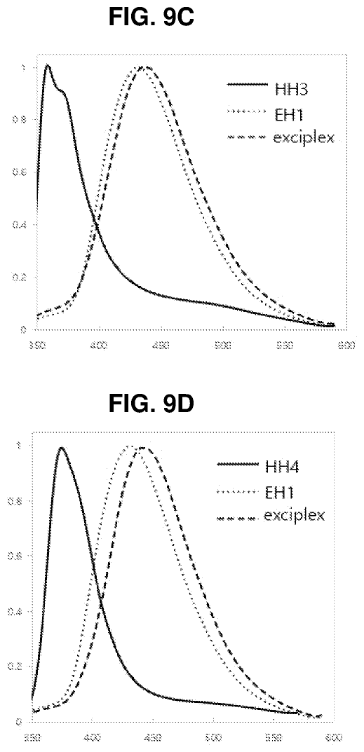

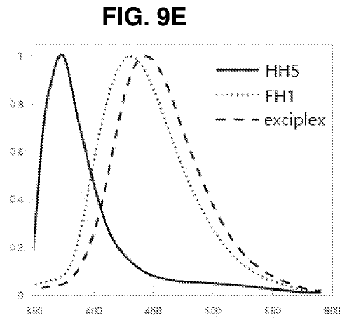

A PL spectrum of a p-type host and an n-type host used in Examples 1 to 5 and an exciplex generated by the p-type host and the n-type host are shown in FIGS. 9A to 9E. (A unit of a horizontal axis is nm.)

A HOMO energy level, a LUMO energy level and a triplet energy (T1) and a maximum emission wavelength (Emax) of the p-type host and the n-type host used in Examples 1 to 5 and a maximum emission wavelength of the exciplex generated by the p-type host and the n-type host are measured and listed in Table 1.

Various methods of determining the HOMO energy level are known to the skilled person. For example, the HOMO energy level can be determined using a conventional surface analyser such as an AC3 surface analyser made by RKI instruments. The surface analyser may be used to interrogate a single film (neat film) of a compound with a thickness of 50 nm. The LUMO energy level can be calculated as follows:

LUMO=HOMO−bandgap.

The bandgap may be calculated using any conventional method known to the skilled person, such as from a UV-vis measurement of a single film with a thickness of 50 nm. For example, this can be done using a SCINCO S-3100 spectrophotometer. The HOMO and LUMO values of the compounds of the examples and embodiments disclosed herein may be determined in this way. Namely, the HOMO and LUMO values may be experimentally or empirically determined values of thin films, such as 50 nm films.

The triplet energy may be measured from a low temperature PL spectrum.

The PL spectrum may be measured using an organic solvent, e.g., toluene, at the room temperature, i.e., 25° C. For example, a thin film having a thickness of 30 nm is formed using a compound solution, which includes a compound dissolved in an organic solvent, e.g., toluene, with a concentration of about 1*10⁻⁵ M, and the PL spectrum can be measured using a fluorescence spectrometer, e.g., a FS-5 fluorescence spectrometer (Edinburgh Instruments).

TABLE 1

| | HOMO | LUMO | Emax | T1 |
|---|---|---|---|---|
| | [eV] | [eV] | [nm] | [eV] |
| HH1 | −5.43 | −2.09 | 386 | 2.98 |
| HH2 | −5.62 | −2.15 | 358 | 2.94 |
| HH3 | −5.61 | −2.11 | 358 | 3.03 |
| HH4 | −5.59 | −2.16 | 373 | 2.96 |
| HH5 | −5.59 | −2.16 | 375 | 3.00 |
| EH1 | −5.80 | −2.80 | 430 | 2.96 |
| exciplex | — | — | 457 | — |

The electrooptic properties, i.e., a driving voltage (V), a brightness (cd/A) and a color coordinate index (CIEy), and a lifespan (LT95), of the OLED in Comparative Examples 1 to 10 and Examples 1 to 5 are measured at 3.0 mA/cm² and listed in Table 2.

TABLE 2

| | V | Cd/A | CIEy | LT95 [h] |
|---|---|---|---|---|
| Ref1 | 3.8 | 18.3 | 0.067 | 81 |
| Ex1 | 3.8 | 24.3 | 0.066 | 110 |
| Ref2 | 3.8 | 17.6 | 0.066 | 75 |
| Ex2 | 3.8 | 18.9 | 0.066 | 91 |
| Ref3 | 3.8 | 16.5 | 0.066 | 43 |
| Ex3 | 3.8 | 16.8 | 0.065 | 51 |
| Ref4 | 3.8 | 17.0 | 0.068 | 36 |
| Ex4 | 3.8 | 17.6 | 0.067 | 50 |
| Ref5 | 3.8 | 16.1 | 0.066 | 41 |
| Ex5 | 3.8 | 16.2 | 0.065 | 55 |
| Ref6 | 3.8 | 13.9 | 0.064 | 10 |
| Ref7 | 3.8 | 14.5 | 0.063 | 11 |
| Ref8 | 3.8 | 14.0 | 0.064 | 11 |
| Ref9 | 3.8 | 14.2 | 0.064 | 16 |
| Ref10 | 3.8 | 13.3 | 0.063 | 19 |

As shown in Table 2, in comparison to the OLED of Comparative Examples 1 to 10, the OLED of Examples 1 to 5 has advantages in at least one of the emitting efficiency and the lifespan.

For example, the compounds A and the compound HH1, the compounds B and the compound HH2, the compounds C and the compound HH3, the compounds D and the compound HH4 and the compounds E and the compound HH5 respectively have a difference in a substitution of an adamantanyl group. However, in comparison to the OLED of Comparative Examples 1 to 5, the OLED of Examples 1 to 5 has significant advantages in the emitting efficiency and the lifespan.

Although the compounds F, G, H, I, and J include an adamantanyl group, the compounds F, G, H, I, and J have a difference in a core than the compounds HH1 to HH5. As shown in Table 2, in comparison to the OLED of Comparative Examples 6 to 10, the OLED of Examples 1 to 5 has significant advantages in the emitting efficiency and the lifespan.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
a first electrode;
a second electrode facing the first electrode; and
a first emitting part including a first emitting material layer and positioned between the first electrode and the second electrode,
wherein the first emitting material layer includes a first p-type host and a first n-type host,
wherein the first p-type host is represented by Formula 1: 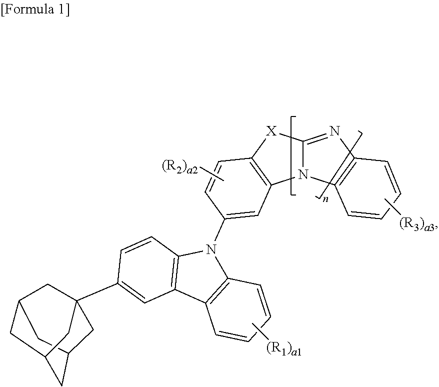
wherein in the Formula 1,
each of a1 and a3 is independently an integer of 0 to 4, a2 is an integer of 0 to 3, n is 0 or 1,
X is NR₄, O, or S,
Each of R₁, R₂, and R₃ is independently selected from the group consisting of hydrogen, deuterium, halogen, cyano, a substituted or unsubstituted C1 to C10 alkyl group, a substituted or unsubstituted C1 to C10 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
R₄ is selected from the group consisting of hydrogen, deuterium, halogen, cyano, a substituted or unsubstituted C1 to C10 alkyl group, a substituted or unsubstituted C1 to C10 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
wherein the first n-type host is represented by Formula 3: 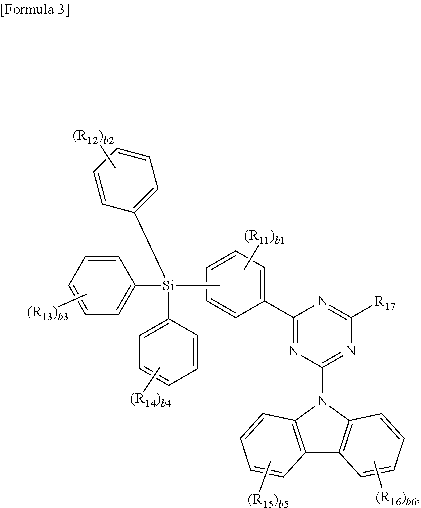
wherein in the Formula 3,
each of b1, b5 and b6 is independently an integer of 0 to 4, each of b2 to b4 is independently an integer of 0 to 5, and
each of R₁₁ to R₁₇ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

2. The organic light emitting diode according to claim 1, wherein the first p-type host includes at least one of compounds in Formula 2:

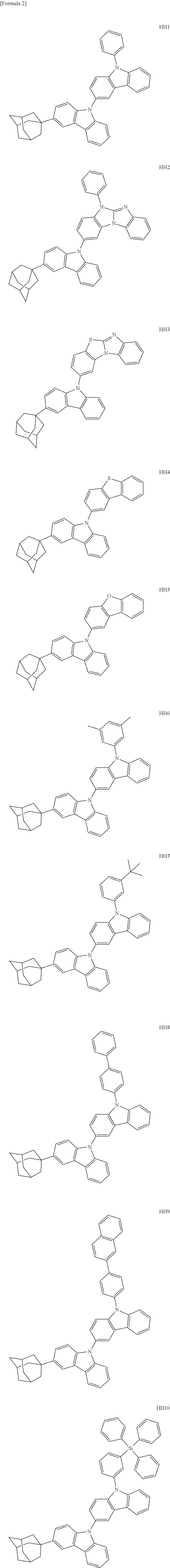

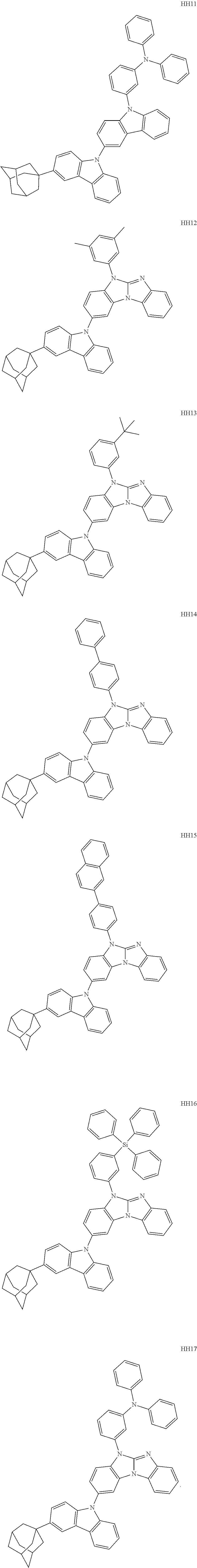

3. The organic light emitting diode according to claim 1, wherein the first n-type host includes at least one of compounds in Formula 4:

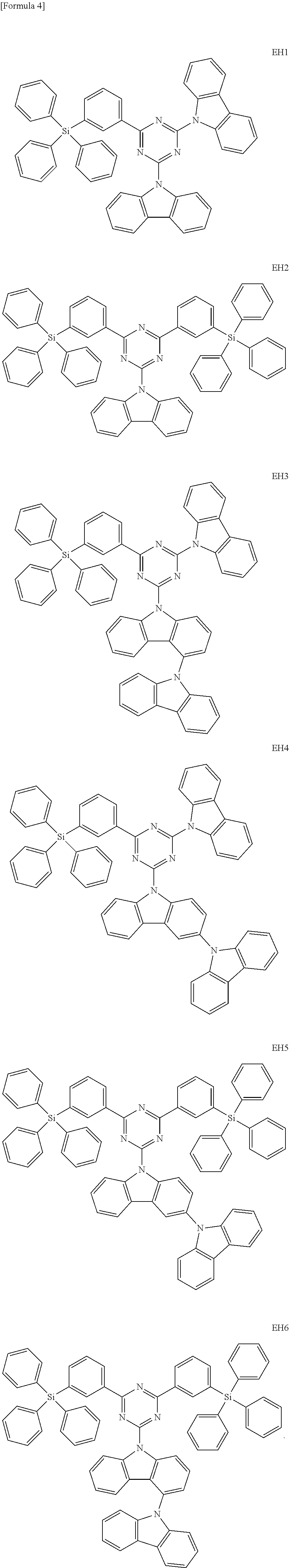

4. The organic light emitting diode according to claim 1, wherein an exciplex is generated by the first p-type host and the first n-type host.

5. The organic light emitting diode according to claim 4, wherein the exciplex has a maximum wavelength being in a range of 435 to 470 nm.

6. The organic light emitting diode according to claim 1, wherein the first emitting part further includes at least one of a hole injection layer, a hole transporting layer, an electron blocking layer, a hole blocking layer, an electron transporting layer, and an electron injection layer.

7. The organic light emitting diode according to claim 1, wherein the first emitting material layer further includes a first dopant.

8. The organic light emitting diode according to claim 7, wherein the first dopant is represented by Formula 5: 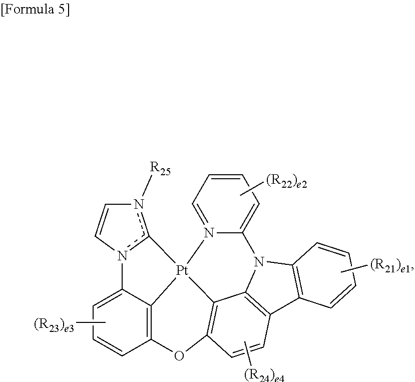
wherein in the Formula 5, each of e1 and e2 is independently an integer of 0 to 4, e3 is an integer of 0 to 3, and e4 is an integer of 0 to 2,
each of R₂₁ to R₂₄ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
R₂₅ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

9. The organic light emitting diode according to claim 8, wherein the first dopant is at least one of compounds in Formula 6:

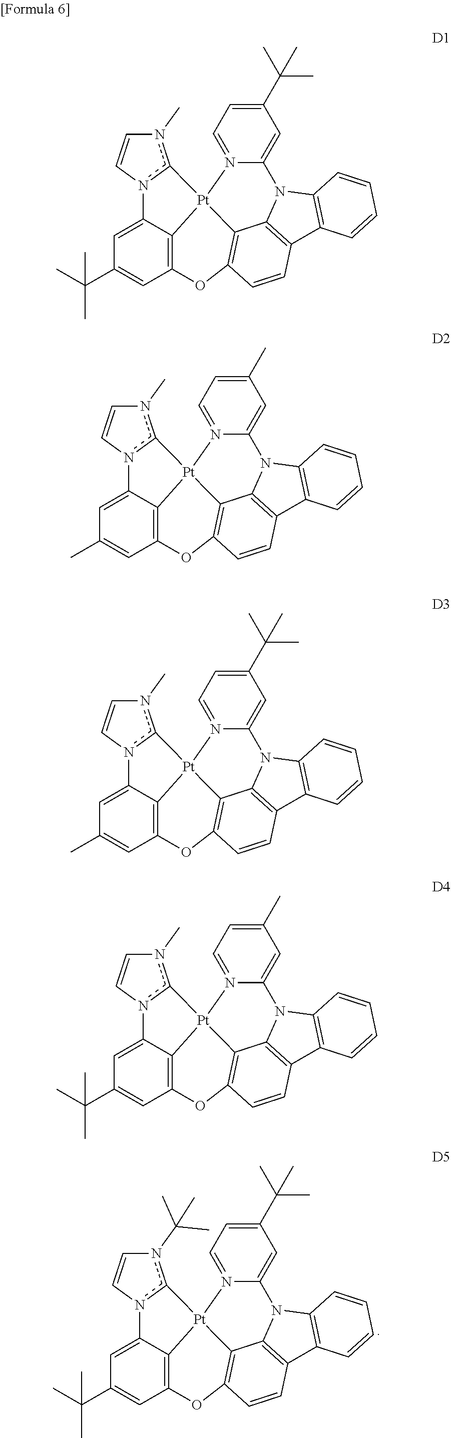

10. The organic light emitting diode according to claim 8, further comprising:
a second emitting part including a second emitting material layer and positioned between the first emitting part and the second electrode,
wherein the second emitting material layer includes a second p-type host, a second n-type host, and a second dopant, and
wherein the second p-type host is represented by the Formula 1, the second n-type host is represented by the Formula 3, and the second dopant is represented by the Formula 5.

11. The organic light emitting diode according to claim 10, wherein the second emitting part further includes at least one of a hole injection layer, a hole transporting layer, an electron blocking layer, a hole blocking layer, an electron transporting layer, and an electron injection layer.

12. The organic light emitting diode according to claim 10, further comprising:
a third emitting part including a third emitting material layer and positioned between the first emitting part and the second emitting part,
wherein the third emitting material layer includes a red emitting material layer and a green emitting material layer.

13. The organic light emitting diode according to claim 1, further comprising:
a second emitting part including a yellow-green emitting material layer and positioned between the first emitting part and the second electrode.

14. An organic light emitting device, comprising:
a substrate;
an organic light emitting diode of claim 1 and disposed over the substrate; and
an encapsulation layer covering the organic light emitting diode.

15. The organic light emitting device according to claim 14, wherein the substrate includes a red pixel region, a green pixel region, and a blue pixel region, and the organic light emitting diode corresponds to the red, green, and blue pixel regions,
wherein the organic light emitting device further comprises: a color filter layer corresponding to the red, green, and blue pixel regions, and
wherein the color filter layer is positioned between the substrate and the organic light emitting diode or over the organic light emitting diode.

16. The organic light emitting device according to claim 14, wherein the substrate includes a red pixel region, a green pixel region, and a blue pixel region, and the organic light emitting diode corresponds to the red, green, and blue pixel regions,
wherein the organic light emitting device further comprises: a color conversion layer corresponding to the red and green pixel regions, and
wherein the color conversion layer is positioned between the substrate and the organic light emitting diode or over the organic light emitting diode.

17. The organic light emitting device according to claim 14, wherein the first p-type host includes at least one of compounds in Formula 2:

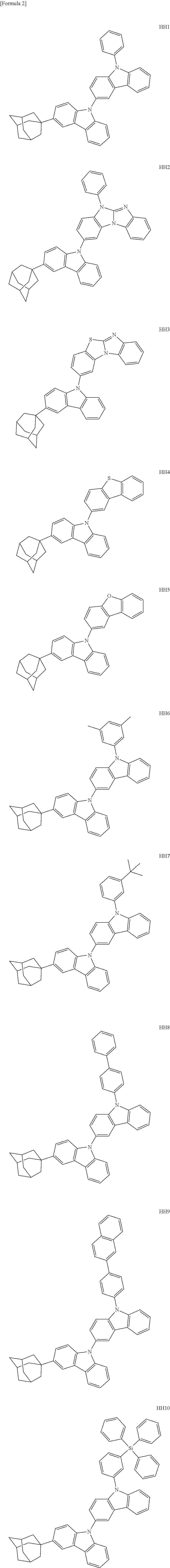

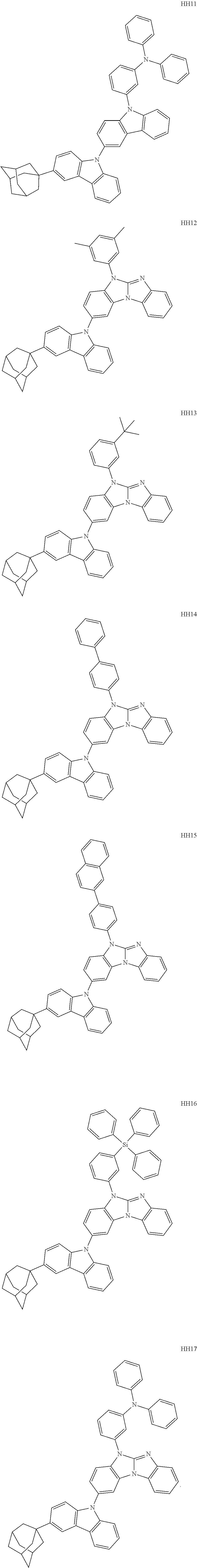

18. The organic light emitting device according to claim 14, wherein the first n-type host includes at least one of compounds in Formula 4:

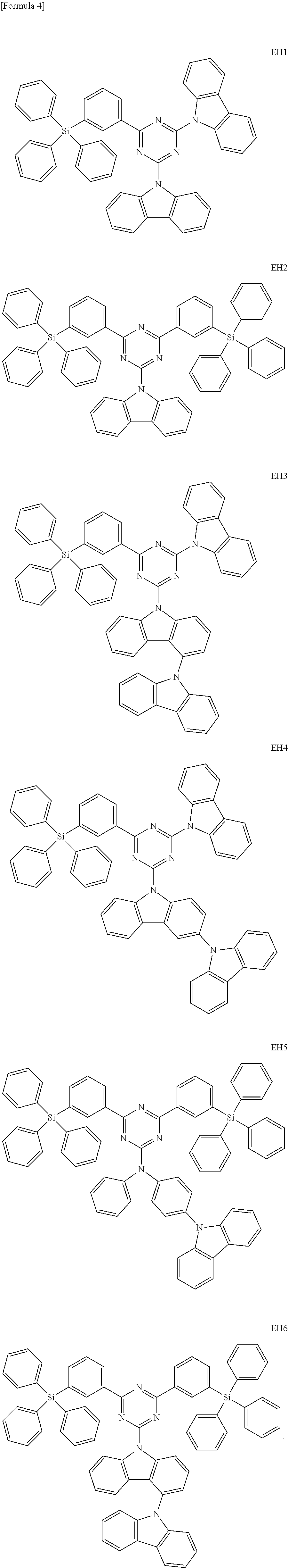

19. The organic light emitting device according to claim 14, wherein an exciplex is generated by the first p-type host and the first n-type host, and the exciplex has a maximum wavelength being in a range of 435 to 470 nm.

20. The organic light emitting device according to claim 14, wherein the first emitting material layer further includes a first dopant.

21. The organic light emitting device according to claim 20, wherein the first dopant is represented by Formula 5: 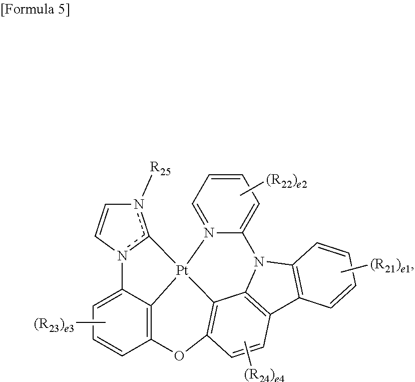
wherein in the Formula 5, each of e1 and e2 is independently an integer of 0 to 4, e3 is an integer of 0 to 3, and e4 is an integer of 0 to 2,
each of R₂₁ to R₂₄ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, and
R₂₅ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

22. The organic light emitting device according to claim 21, wherein the first dopant is at least one of compounds in Formula 6: [chemical structure]
